(19) United States
(12) Patent Application Publication
(10) Pub. No.: US 2025/0015563 A1
(43) Pub. Date: Jan. 9, 2025

(54) SYSTEMS AND METHODS FOR BEAM COMBINATION OF TAPERED DIODE LASERS AND AMPLIFIERS

(71) Applicant: Freedom Photonics LLC, Goleta, CA (US)

(72) Inventors: Jenna Nicole Campbell, Santa Barbara, CA (US); Paul Orville Leisher, Livermore, CA (US); Michelle Helena Labrecque, Goleta, CA (US); Christopher Barrowclough Ebert, Longmont, CO (US)

(21) Appl. No.: 18/761,160

(22) Filed: Jul. 1, 2024

Related U.S. Application Data
(60) Provisional application No. 63/511,838, filed on Jul. 3, 2023.
(60) Provisional application No. 63/511,834, filed on Jul. 3, 2023.

(51) Int. Cl. H01S 5/40; H01S 5/026; H01S 5/04; H01S 5/062; H01S 5/0683

(52) U.S. Cl. CPC H01S 5/4012; H01S 5/0268; H01S 5/041; H01S 5/062; H01S 5/0683

(57) ABSTRACT

A light source generates a high brightness combined light beam by coherently combining a plurality of light beams generated or amplified by an optical array comprising a plurality flared optical gain regions. The plurality of light beams generated or amplified by the optical array can have a common wavelength and can be passively or actively phase locked and coherently combined to generate the combined light beam. The plurality of light beams generated or amplified by the optical array can have different wavelengths and can be spectrally combined to generate the high brightness light beam. The radiance of the high brightness light beam can be greater than the radiance of the individual light beams, and its beam quality can be close to the beam quality of the individual light beams.

### INCORPORATION BY REFERENCE TO ANY PRIORITY APPLICATIONS

This application claims the benefit of priority of U.S. Provisional Application No. 63/511,838 titled “SYSTEMS AND METHODS FOR ACTIVE BEAM COMBINATION OF TAPERED DIODE LASERS AND AMPLIFIERS” (Docket No. FREDOM.035PR1), which was filed on Jul. 3, 2023, and Provisional Application No. 63/511,834 titled “SYSTEMS AND METHODS FOR PASSIVE BEAM COMBINATION OF TAPERED DIODE LASERS AND AMPLIFIERS” (Docket No. FREDOM.035PR2), which was filed on Jul. 3, 2023. The entirety of each application referenced in this paragraph is expressly incorporated herein by reference.

### STATEMENT REGARDING FEDERALLY SPONSORED R&D

This invention was made with U.S. Government support under Contract number 22-S&A-0725, awarded by the Department of Defense (Joint Directed Energy Transition Office), and Contract number HQ-0860-22-C-0010 awarded by the Missile Defense Agency (MDA). The Government has certain rights in the invention.

### BACKGROUND

### Field of the Invention

Various embodiments of this application relate to the high power diode laser arrays, and in particular, combining laser beams generated by individual laser elements of the semiconductor diode laser array.

### SUMMARY OF THE INVENTION

Various designs and methods described herein are capable of combining high quality light beams (e.g., laser beams) output by laser and/or amplifier elements of an array of lasers and/or optical amplifiers having flared optical gain regions. Some systems and methods disclosed herein utilize the incorporation of a passive or active optical phase locking to make elements of the laser array or the optical amplifier array, operate in phase and enable coherent combination of the output light beams to generate a single wavelength high brightness light beam. Some other systems and methods disclosed herein use the laser and the optical amplifier elements, having flared optical gain regions, to generate light beams having different wavelengths and spectrally combine these light beams to generate a multi-wavelength high brightness light beam.

In one aspect, an optical system for generating a combined light beam by combining a plurality of light beams, where the optical system includes: a source laser and an optical array chip comprising a plurality of optical amplifiers configured to receive light from the source laser and output the plurality of light beams. An individual optical amplifier of the plurality of the optical amplifiers includes: a first waveguide section extending from a first end to a second end in a longitudinal direction and a second waveguide section extending from the second end to a third end in the longitudinal direction, a first electrode disposed on the first waveguide section, and a second electrode disposed on the second waveguide section. The second waveguide section comprises a flared optical gain section that has an output lateral width at the third end larger than an input lateral width at the second end, and supports propagation of at least two lateral modes. The second electrode is electrically isolated from the first electrode. The optical system further includes an electronic system configured to adjust a voltage or current provided to the first electrode to increase a brightness of the combined light beam.

In another aspect, an optical system for generating an combined light beam using a plurality of laser beams produced by a plurality of coupled external cavity lasers; the optical system includes: an optical array chip comprising a plurality of optical gain elements, wherein an individual optical gain element comprises a waveguide region extending from a back end to a front end of the individual optical gain element along a longitudinal direction, the waveguide region comprising a reflector, and a flared optical gain region having an output lateral width closer to the front end larger than an input lateral width closer to the back end. At least a portion of the waveguide region supports propagation of at least two lateral modes. The optical system further includes a cavity coupler region configured to couple light from an individual optical gain element to one or more other optical gain elements of the optical array chip forming the plurality of coupled external cavity lasers.

In another aspect, an optical system for generating an combined light beam from a plurality of laser beams produced by a plurality of evanescently coupled light sources; the optical system includes: a plurality of evanescently coupled waveguides, wherein an individual waveguide comprises at least a first reflector, and an optical array chip comprising a plurality of optical gain elements, wherein an individual optical gain element of the plurality of optical gain elements comprises a waveguide region extending from a back end to a front end of the individual optical gain element along a longitudinal direction, the waveguide region comprising a second reflector and a flared optical gain region having an output lateral width closer to the front end larger than an input lateral width closer to the back end. At least a portion of the waveguide region supports propagation of at least two lateral modes. The individual waveguides of the plurality of evanescently coupled waveguides are optically connected to respective individual optical gain elements of the optical array chip to form the plurality of evanescently coupled light sources.

In another aspect, an optical system for generating a combined light beam using a plurality of laser beams having different wavelengths, the plurality of laser beams generated by a plurality of light sources; the optical system includes: an optical array chip comprising a plurality of optical gain elements, wherein an individual optical gain element comprises a waveguide region extending from a back end to a front end of the individual optical gain element along a longitudinal direction, the waveguide region comprising a flared optical gain region having an output lateral width closer to the front end larger than an input lateral width closer to the back end, where at least a portion of the waveguide region supports propagation of at least two lateral modes. The optical system further comprises a beam combiner configured to receive the plurality of laser beams from the optical array chip and generate the combined light beam. The flared optical gain region at least partially generates or amplifies an individual laser beam of the plurality of laser beams, the individual laser beam comprising a first wavelength different from wavelengths of other laser beams in the plurality of laser beams.

### BRIEF DESCRIPTION OF THE DRAWINGS

In the following description of the various embodiments, reference is made to the accompanying drawings which form a part hereof, and in which is shown by way of illustration various embodiments of the device. It is to be understood that other embodiments may be utilized and structural changes may be made.

FIG. 1A is a block diagram illustrating an example optical system for generating a high brightness light beam by combining a plurality of light beams generated using a seed light source and an array of optical gain sections having flared optical gain regions.

FIG. 1B is a block diagram illustrating another example optical system for generating a high brightness light beam by combining a plurality of light beams generated using an array of coupled light sources.

FIG. 1C illustrates various laser and optical amplifier designs that may be included in the array of optical gain sections or light sources of the optical systems shown in FIG. 1A or FIG. 1B.

FIG. 1D illustrates a cross-section of a flared optical gain region generated by a patterned top electrode.

FIG. 2A schematically illustrates coherent and in-coherent combination of light beams generated by a plurality of laser sources having flared optical gain regions and/or amplified by a plurality of optical amplifiers having flared optical gain regions.

FIG. 2B schematically illustrates spectral combination of light beams generated by a plurality of external cavity laser sources having flared optical gain regions.

FIG. 3A is an example power and efficiency performance of a single light source that includes a laser and an optical amplifier having a flared optical gain region.

FIG. 3B is an example beam propagation factor performance of a single light source that includes a laser and an optical amplifier having a flared optical gain region.

FIG. 4A illustrates an example optical system for generating a single wavelength high brightness light beam using a seed laser and an array of phase controlled optical gain sections having flared optical gain regions.

FIG. 4B illustrates an example optical system for generating a single wavelength high brightness beam of light using a seed laser and an array of phase controlled optical gain sections having flared optical gain regions, where the flared and non-flared optical gain regions of the individual optical gain sections are pumped and/or controlled using isolated electrodes.

FIG. 4C illustrates a photonic chip including an optical distribution region monolithically integrated with an array of optical gain sections having flared optical gain regions.

FIG. 5A illustrates an example optical system for generating a high brightness light beam, the optical system having a super-mode cavity formed by a laser coupler section placed in the front side of an optical array comprising flared optical gain regions.

FIG. 5B illustrates an example optical system for generating a high brightness light beam, the optical system having a super-mode cavity formed by a laser coupler section placed in the back side of an optical array comprising flared optical gain regions.

FIG. 5C illustrates an example optical system for generating a high brightness light beam, the optical system having a super-mode cavity formed by a laser coupler section placed in the back side of an optical array comprising phase controlled and flared optical gain regions.

FIG. 6A illustrates an example optical system for generating a high brightness light beam using an array of evanescently coupled seed lasers and flared optical gain regions. Since the seed laser sources are evanescently coupled, the light beams generated by these laser sources are phase-locked and after optical amplification the resulting light beams can be coherently combined to generate the high brightness beam.

FIG. 6B illustrates an example optical system for generating a high brightness light beam using an array of evanescently coupled light sources and flared optical gain regions.

FIG. 7A illustrates an example optical system for generating a multi-wavelength high brightness light beam using an array of seed lasers having different wavelengths and optical amplifiers having flared optical gain region.

FIG. 7B illustrates an example optical system for generating and steering a multi-wavelength high brightness light beam using an array of seed lasers having different wavelengths and optical amplifiers having flared optical gain regions.

FIG. 7C illustrates an example optical system for generating a multi-wavelength high brightness optical pattern using an array of seed lasers having different wavelengths and optical amplifiers having flared optical gain regions.

FIG. 8 illustrates another example optical system for generating a multi-wavelength high brightness light beam using an array of seed lasers having different wavelengths and optical amplifiers having flared optical gain regions.

### DETAILED DESCRIPTION

Although certain preferred embodiments and examples are disclosed below, inventive subject matter extends beyond the specifically disclosed embodiments to other alternative embodiments and/or uses and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied using a variety of techniques including techniques that may not be described herein but are known to a person having ordinary skill in the art. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein. It will be understood that when an element or component is referred to herein as being “connected” or “coupled” to another element, it can be directly connected or coupled to the other element or intervening elements may be present therebetween. For clarity of description, “reflector” or “mirror” can be used interchangeably to refer to an optical element and/or a surface having a reflectivity greater than or equal to about 5% and less than or equal to 100%. For example, an optical element and/or a surface having a reflectivity greater than or equal to about 5% and less than or equal to 99%, greater than or equal to about 10% and less than or equal to 90%, greater than or equal to about 15% and less than or equal to 80%, greater than or equal to about 20% and less than or equal to 70%, greater than or equal to about 30% and less than or equal to 60%, or any value in any range/sub-range defined by these values can be considered as a reflector or mirror. It will be understood that “light having single wavelength”, “light beam having single wavelength”, “laser light having single wavelength”, “single wavelength light” or “single wavelength laser light”, can be light comprising wavelengths within a continuous wavelength or frequency band (e.g., a narrowband) centered at a center wavelength (or center frequency). It will be understood that, in some cases, “light having multiple wavelengths”, “multi-wavelength laser light”, “multi-wavelength light beam” or “multi-wavelength light”, can be light comprising wavelengths within a wavelength or frequency band (e.g., a wideband) having a spectral shape comprising a flat, near flat, or multi-peak region. In some cases, It will be understood that, in some cases, “light having multiple wavelengths”, “multi-wavelength laser light”, “multi-wavelength light beam” or “multi-wavelength light”, can be light comprising multiple frequency bands (e.g., narrow bands) centered at multiple center wavelengths (or center frequencies). It will be understood that “brightness” of a light beam output by a light source or an optical amplifier as used herein, is proportional to the radiance of the light beam (unit: W/sr·m²).

High power light beams (e.g., laser beams) are required in many applications, including but not being limited to directed energy, light detection and range finding (LIDAR), remote sensing, power beaming, free space optical communications, laser cutting and welding, and medical procedures. The power level of a high power light beam can be as large as hundreds of watts or kilowatts in some cases. In many cases, such high power light beams are generated by solid-state, fiber, or gas lasers that are pumped by semiconductor laser diodes (e.g., laser diode bars or arrays). Beyond their use as pump lasers, in some applications, laser diode bars or arrays can serve as standalone sources of high power light beams. In both cases, used as pump or standalone sources, the radiance (or brightness) of the light beam generated by these semiconductor lasers can affect the efficiency of optical energy transfer to a target region or medium (e.g. an optical gain medium of another laser). In some cases, the radiance of the light beam can be increased by improving the intensity of the light beam and/or improving its beam quality. In some cases, the brightness of a light beam may be quantified as radiance (or radiant flux per unit area per unit solid angle). Thus, as used herein, brightness of light beam can jointly represent the beam quality and optical intensity of a light beam.

In some cases, a high brightness light beam may be generated by combining the output of a plurality of high-power light beams (e.g., laser beams). Beam combining may comprise coherent combination of light beams having substantially the same wavelengths or spectral beam combination of light beams having different wavelengths. As such beam combing methods may be divided into two major categories coherent beam combining (CBC) and spectral beam combining (SBC).

SBC and CBC may be used to combine the high power light beams (e.g., laser beams) output by a plurality of lasers or optical amplifier elements in a laser or optical amplifier array (herein collectively referred to as optical array), to generate a high power and high intensity light beam having a beam quality similar or close to that of a light beam generated by an individual element of the optical array. In some cases, a high power light beam can be a high intensity and high brightness light beam. In some examples, for a given optical power carried by a light beam, the brightness (or radiance) of the light beam may increase as its intensity increases and/or its beam quality improves.

In some cases, SBC and/or CBC may be used to combine N light beams output by N constituent laser (and/or optical amplifier) elements to generate a high power light beam having an optical power, radiance, and/or brightness close or equal to N times the optical power of a light beam output by an individual element of the corresponding optical array. In some cases, SBC and/or CBC may be used to combine N output light beams output by N constituent laser (and/or optical amplifier) elements to generate a high brightness light beam having a far field optical intensity close or equal to N² times of an optical intensity of a light beam output by an individual element of the optical array. The beam quality of the high brightness light beam can be the same as or substantially the same as the beam quality of an individual light beam output by a constituent laser (and/or optical amplifier) element of the optical array. In some examples, beam quality may be quantified using beam parameter product (BPP), which is the product of the near-field beam waist and the far-field divergence angle, and/or using M² or BPP/(λ/π), where λ is the center wavelength of the light beam.

Coherent beam combination (CBC) can include controlling (e.g., locking) the phases (e.g., relative phases) of a plurality of light beams having substantially the same wavelength and coherently combining them to generate a high brightness single wavelength light beam. In some cases, these light beams may be generated by a laser array or output by an amplifier array. The laser array or the optical amplifier array may comprise elements having cavities and/or optical gain regions (including flared optical gain regions) that sustain and/or amplify wavelengths substantially in the same wavelength range. In these cases, locking the phases of the light beams may comprise actively or passively controlling the elements of the laser and/or amplifier array such that all elements of the array operate in phase at a single frequency (or wavelength). Accordingly, CBC includes active CBC and passive CBC. As an example, active CBC may comprise distributing the light output by a seed optical source (e.g., a single mode laser) to elements of an array of optical amplifiers causing the generation of a combined beam (e.g., a high brightness beam), having substantially the same wavelength as the seed optical source and a brightness or radiance proportional to a number of amplifier elements or larger. In some cases, the seed optical source may be distributed among the elements of a laser array to lock the phases of light beams generated by the laser array causing the generation of a combined beam of light (e.g., a brightness light beam). Active CBC may further comprise electrically controlling a region of individual array elements to increase the brightness or radiance of the combined light beam resulting from combining the corresponding individual light beams.

Spectral beam combination (SBC) can include combining a plurality of light beams having different wavelengths (or different center wavelengths) to generate a multi-wavelength high brightness light beam. The plurality of light beams may be generated by different laser elements of a laser array and amplified by an array of optical amplifiers. In various implementations, the plurality of light beams are combined using a reflective or a transmissive diffraction grating, an array of dichroic beamsplitters, or other optical devices that can combine (e.g., spatially overlap) light beams having different wavelengths. By properly arranging the angles of incidence light beams having different wavelengths on a grating or a dichroic array, for example, the diffracted or reflected light beams may be spatially overlapped to generate a multi-wavelength high brightness light beam having a beam quality the same as or close or similar to that of an individual light beam used to generate the multi-wavelength high brightness light beam.

In some cases, the optical array may comprise an array of optical gain elements (e.g., flared optical gain elements) where the optical gain elements are included in an external cavity configuration to form a plurality of external cavity lasers that generate a plurality of the light beams. In some cases, where the plurality of the light beams are generated by the external cavity lasers in a super-mode cavity configuration, the light beams may be combined using CBC. In some cases, where the plurality of the light beams generated by the external cavity laser have different wavelengths, the external cavities may comprise a grating and a front reflector shared among the external cavities, the grating and a front reflector serving as a beam combiner for SBC.

SBC and CBC can be used to combine the beams output by a diode laser array or a semiconductor optical amplifier (SOA) array to generate a high intensity and confined light beam and/or a multi-wavelength beam. In some cases, a laser source of a laser array or an SOA amplifier of an SOA array may include a flared optical gain region (herein referred to as flared optical gain region). In some implementations, a flared optical gain region may provide a higher level of optical gain to an input light beam or a light beam sustained in a laser cavity, compared to a non-flared optical gain region (e.g., a single mode non-flared region), while preserving a fundamental lateral mode profile (e.g., a Gaussian, or near Gaussian profile) of the light beam as propagates in the gain region. As such, a diode laser or an SOA having a flared gain region can generate light beams having higher brightness and/or better beam quality, e.g., compared to their counterpart broad area lasers. In some cases, a flared optical gain region may comprise a waveguide region or waveguide layer (e.g., a semiconductor waveguide region or layer) that supports propagation of high order lateral modes but is configured to provide a higher optical gain to the fundamental lateral mode. In some examples, a flared optical gain region may comprise a flared waveguide and/or a flared pumped region (e.g., pumped using a flared electrode) of a flared or non-flared waveguide. Examples of flared lasers and flared optical amplifiers having flared optical gain regions and flared electrodes (e.g., patterned flared electrodes, or patterned and segmented flared electrodes) are discussed in U.S. patent application Ser. No. 17/806,460 (Attorney Docket No. FREDOM.026A2) filed on Jun. 10, 2022, which is hereby incorporated by reference herein in its entirety.

Combining light beams output by a diode laser array or an SOA array comprising elements having a flared gain region can generate a light beam having a greater radiance, optical power, and potentially higher beam quality compared to a light beam generated by combining light beams output by a diode laser array comprising broad area diode lasers or an SOA array having non-flared optical gain regions.

The proposed configurations disclosed herein comprise implementation of CBC and SBC techniques using diode laser arrays, SOA arrays, master oscillator-optical amplifier (MOPA) arrays having flared optical gain regions, to provide a light source (e.g., comprising semiconductor) that generates a high brightness, potentially diffraction limited (or near diffraction limited), light beam without the need for a brightness converter (a gas or a solid-state laser pumped by a low brightness light beam). This approach reduces or potentially eliminates the cost, complexity, and efficiency loss associated with a hybrid light source comprising a gain medium (e.g., a non-semiconducting gain medium) pumped by a laser diode, a MOPA, a laser diode array, or a MOPA array. Additionally, the disclosed designs and methods may be implemented in new ways to enable new functionalities. For example, a CBC system may be actively controlled to: steer a combined beam (e.g., for LIDAR applications), tune an optical quality of the combined beam, generate optical patterns or any combination thereof. For example, by controlling relative phases of individual light beams in a SBC or CBC based optical system, a direction of propagation and/or a far-field or near-field intensity distribution of the output light beam can be controlled.

Conventional broad area diode lasers can have a high efficiency but can also fail to generate high quality (e.g., diffraction limited) light beams. A competitive advantage of the optical systems and techniques disclosed herein includes using CBC and SBC for generating high brightness and high-quality light beams using a plurality of tapered or flared diode lasers and/or optical amplifiers comprising flared laser or amplifier elements that can generate or amplify high quality individual beams with a relatively high efficiency. In some cases, the resulting combined light beam may have the same quality as an individual light beam but with a higher optical power, intensity, brightness or any combination thereof. In some cases, a light beam generated by SBC or CBC can have a far-field intensity close to (e.g., within 25%, 20%, 15%, 10%, 5%, 2%, 1% of) N² times larger than that of an individual light beam having the same cross-sectional area, where N is the number of light beams that are combined. A beam combined system based on tapered or flared laser diodes and/or optical amplifiers can have higher brightness compared to light sources within the same optical power range based on single mode or broad area diode lasers.

Many applications may benefit from efficient optical sources that generate high power, high brightness, and high quality light beams based on the inventive features disclosed below. Example applications include but are not limited to, directed energy, LIDAR, power beaming, free space optical communications, industrial applications, and medical applications. In addition to the inherent power scaling advantage of beam combination, many of these applications may also benefit from the ability of the disclosed optical sources to steer the combine light beam, tune the beam quality of the combined light beam, and/or generate arbitrary light patterns (far field or near field light patterns).

In addition to their application as standalone sources of potentially high quality, high power, and/or high brightness light beams, the optical systems described below may be used as pump lasers for pumping other lasers. For example, the higher brightness of light beams generated by these optical systems may potentially increase amount of optical power that can be coupled into an optical fiber or crystalline gain media. This advantageous performance feature may enable the use of fewer pump diodes or a smaller fiber laser or solid-state laser for equivalent performance and/or facilitate thermal management of these systems. In some cases, the multi-wavelengths light beams generated using SBC and flared optical gain media, may enable utilization of broad absorption lines in an optical gain medium, which is being pumped by these light beams, to increase an amount of absorbed pump power, or allow the pumping of distinct absorption lines.

An advantage of a semiconductor based light source or optical amplifier over solid-state (non-semiconductor) and fiber based light sources or optical amplifiers lasers is the flexibility of generating and/or amplifying any wavelength within a relatively broad gain bandwidth of the corresponding semiconductor optical gain medium. The operating wavelength range of the optical systems described here may also be expanded by using different semiconductor gain media. The available operating wavelengths of these optical systems may span visible, near infrared and mid infrared spectral regions. For example, GaN material platform may be used for wavelengths in the range 220 nm-500 nm, GaAs material platform may be used for wavelengths in the range between 630 nm-1100 nm, InP material platform may be used for wavelengths in the range 1200-2100 nm, and InSb material platform may be used for wavelengths in the range 1500-5000 nm. In various implementations, other compound semiconductor materials including but not limited to GaAs, AlGaAs, InGaAs, InGaAsP, AlInGaAs, GaInAsSb, InAsSb, PbSe, PbTe, or any combination of these materials, can be used to generate or amplify a desired wavelength.

As described above, a high brightness and high quality light beam can have many advantages over light beams carrying the same amount of optical power but having a low brightness and/or beam quality. In some examples, a combined light beam generated by the optical systems described below can have an optical power and a radiance that is N times larger than the optical power and the radiance of an individual light beam of the N light beams used to generate the combined light beam. In some cases, the individual light beam can have an optical power from 1 to 10 Watts, from 10 to 20 Watts, from 20 to 30 Watts, from 30 to 40 Watts, from 40 to 50 Watts, or any ranges formed by any of these values or larger or smaller values. The radiance of the individual light beam can be from 5 to 10 Watts/microsteradian millimeter squared (W/μsr·mm²), from 5 to 10 W/μsr·mm², from 10 to 50 W/μsr·mm², from 50 to 100 W/μsr·mm², from 100 to 200 W/μsr·mm², from 200 to 300 W/μsr·mm², from 300 to 400 W/μsr·mm², from 400 to 500 W/μsr·mm², or any ranges formed by these values or larger or smaller values.

In some examples, the BPP quality of a high power light beam (along one or both of a fast and a slow-axis) generated by the optical systems (e.g., arrays) disclosed below may be close to that of a diffraction-limited Gaussian beam (e.g., equal to or within 20%, 15% 10%, 5%, 2%, 1% of λ/π, where λ is the wavelength or center wavelength of the light beam or any range formed by any of these values or possibly larger or smaller).

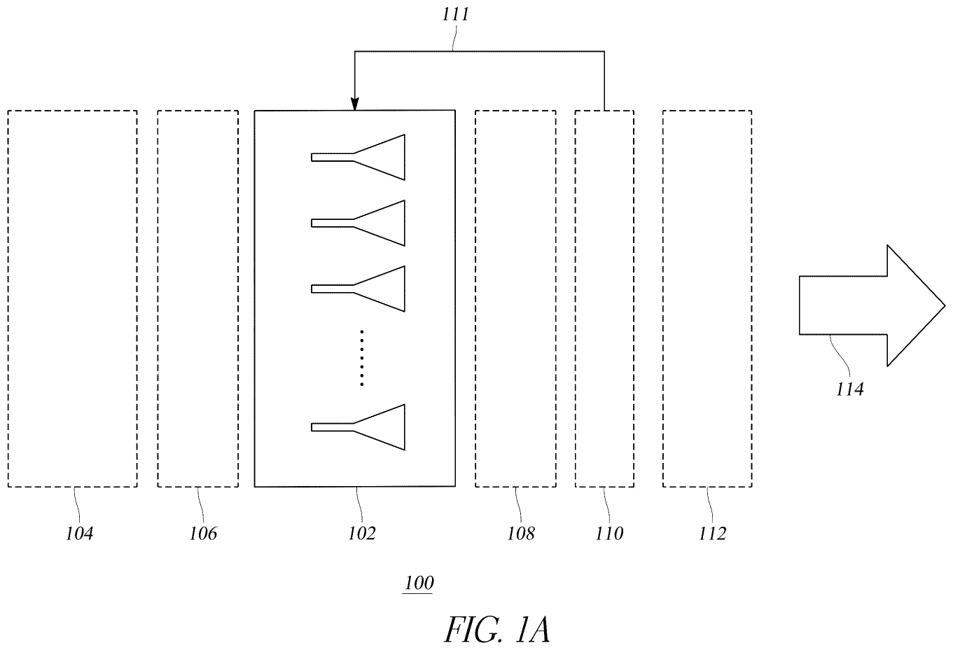

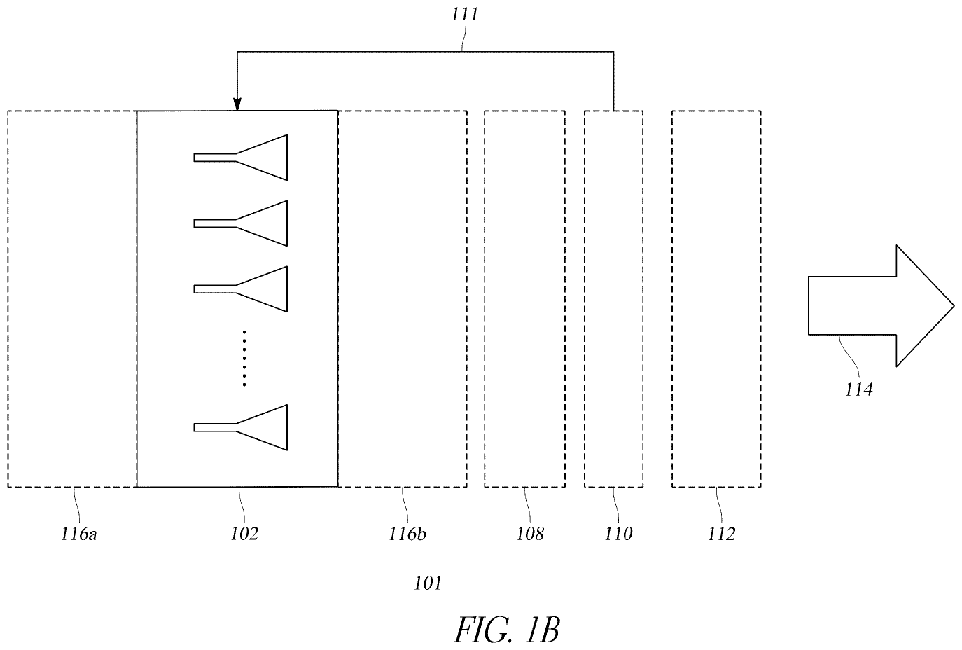

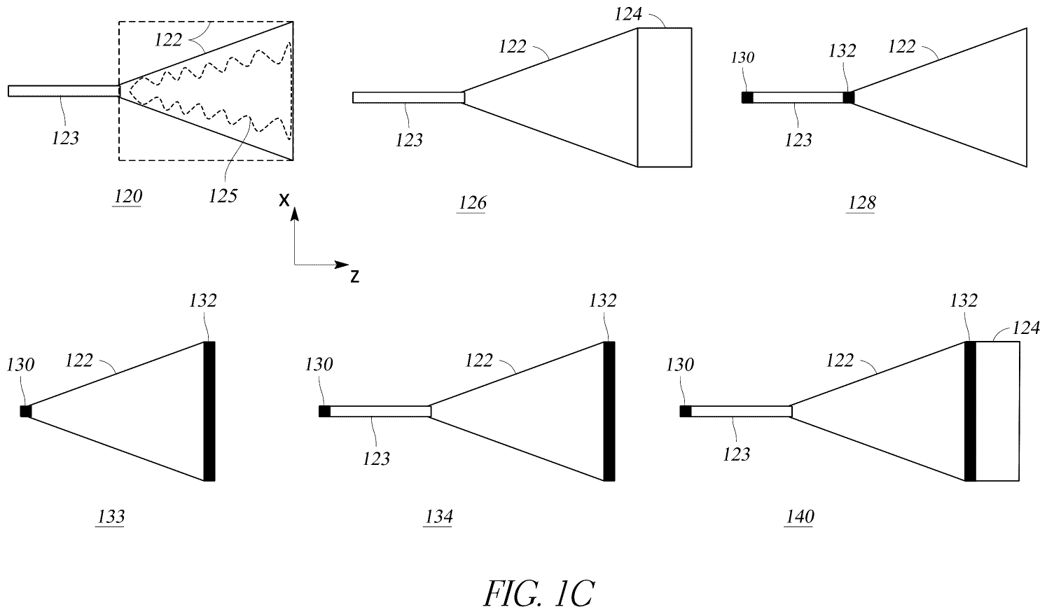

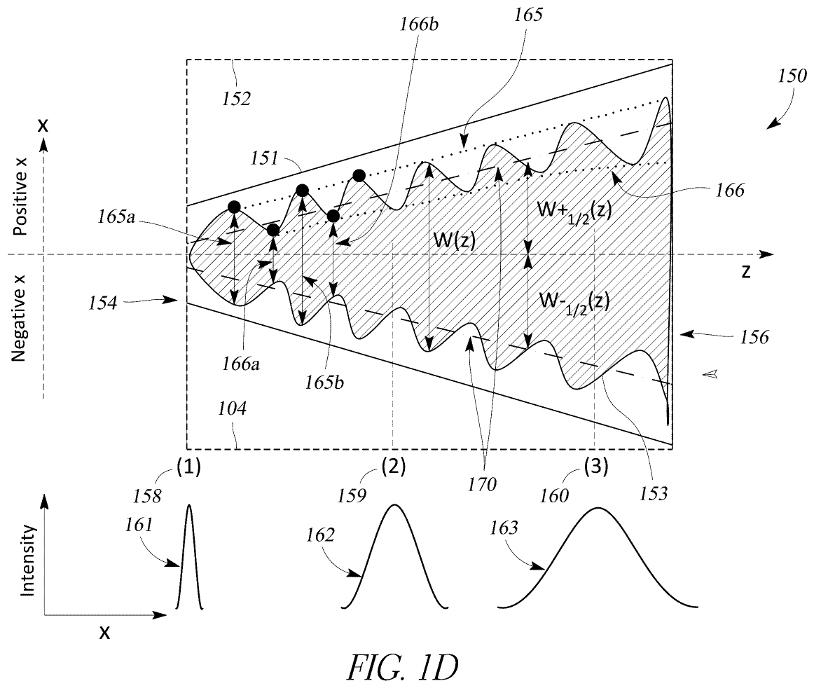

FIG. 1A is a block diagram illustrating an optical system 100 for generating a combined light beam 114 (a high brightness light beam or a diffraction limited high brightness beam) by combining light beams amplified by an optical array 102 comprising individual optical gain sections (or optical gain elements) where at least one optical gain section comprises a flared optical gain region. The optical system 100 may comprise the optical array 102, and one or more of a light source 104 (also referred to as seed source), an optical coupling section 106, a beam transforming section 108, a feedback section 110, and a beam combining section 112. In some implementations, the optical array (or optical array chip) 102 may comprise a photonic chip or an integrated photonic circuit. For example, the optical array 102 may comprise a plurality of optical gain sections monolithically fabricated on a single substrate. In these implementations, the optical array 102 maybe referred to as optical array chip 102. In some cases, an optical gain section can be optically coupled to a passive waveguide (that does not provide optical gain) where the passive waveguide and the optical gain section are monolithically fabricated on a single substrate.

In some cases, an individual optical gain section of the optical array 102 may comprise a non-flared waveguide region optically connected to the flared optical gain region. In some cases, the non-flared waveguide region may comprise optical gain. In some cases, the non-flared waveguide region may comprise a straight ridge or buried waveguide. In some cases, a flared optical gain region may comprise a waveguide region extending from a first end (e.g., input port) to a second end (e.g., an output port) in a longitudinal direction, where the waveguide region supports propagation of at least one high order lateral optical mode and is configured to provide more optical gain to a fundamental lateral mode. In some examples, the flared optical gain region may have a lateral width, in a lateral direction, which increases (linearly or non-linearly) from the first end to the second end. In some cases, the flared optical gain region may be formed in a flared or non-flared waveguide. In some cases, the flared waveguide region may have a lateral width that increases along the longitudinal direction. The lateral direction is perpendicular to the longitudinal direction and parallel to a major surface of the optical array 102 (e.g., to a major surface of an optical array chip). In some cases, the lateral width is substantially constant along the longitudinal direction. In some examples, at least in a longitudinal portion of the waveguide region the lateral width is large enough to support propagation of at least one higher order lateral mode.

The flared optical gain region may comprise a flared electrode and/or flared dielectric layer having a lateral width or an average lateral width that increases (linearly or non-linearly) from the first end to the second of the flared optical gain region. The flared electrode and/or flared dielectric layer may be configured to generate an injection current distribution, within an active layer of the flared optical gain region, having a flared shape causing the formation of a flared shape pumped gain region.

In some cases, an optical gain region may comprise a material that can provide optical gain to light having a wavelength within a gain bandwidth upon being pumped (e.g., by current injection or by optical pumping). In some cases, an optical gain region may comprise a semiconductor material (e.g., a compound semiconductor material). For example, the optical gain region may include, e.g., III-V semiconductor material, or compound semiconductor materials including but not limited to GaN, InP, GaAs, AlGaAs, InGaAs, InGaAsP, AlInGaAs, GaInAsSb, InAsSb, InSb, PbSe, PbTe, or any combination of these materials. In some cases, an optical gain region may comprise a ceramic laser gain media, rare-earth-doped laser gain media, or transition-metal-doped laser gain media. In some examples, the optical array 102 may be fabricated on a chip or a substrate. For example, the optical array 102 may comprise waveguide regions monolithically fabricated on the substrate. In some cases, an optical array 102 can be pumped using individual electrodes disposed on individual optical gain sections or amplifier elements of the optical array 102 where the individual electrodes are electrically isolated. In some other cases, at least a group of optical gain sections can be pumped with a single shared electrode. In some implementations, at least two different regions of an individual optical gain section (e.g., a flared and a non-flared region) may be pumped using two isolated electrode sections.

In some cases, a flared optical gain region may comprise a flared and/or segmented electrode configured to control a distribution of injection current across the flared optical gain region such that a single lateral mode profile of an input light beam is preserved as the light beam passes through the pumped flared optical gain and is amplified. Examples of flared lasers and flared optical amplifier having segments and/or patterned electrodes are discussed in U.S. patent application Ser. No. 17/806,460 (Attorney Docket No. FREDOM.026A2) filed on Jun. 10, 2022, which is hereby incorporated by reference herein in its entirety.

In some cases, the optical array 102 may comprise an array of optical amplifier elements where an individual element includes at least one flared optical gain region. In some cases, an optical amplifier element (also referred to an amplifier element) may comprise a semiconductor optical amplifier (SOA).

In some cases, the optical array 102 may comprise an array of laser elements where an individual laser element includes an optical cavity and an optical gain region within the optical cavity. The optical gain region within the cavity can be a flared or non-flared optical region or a combination thereof.

In some cases, the optical array 102 may comprise an array of light sources where an individual light source includes a laser (a master oscillator) optically connected to an optical amplifier (power amplifier); the combined laser-amplifier device may be referred to as a master oscillator power amplifier (MOPA). In some cases, at least one of the laser and the optical amplifier of a MOPA may comprise a flared optical gain.

In some implementations, the light source 104 generates at least one light beam. In some cases, the light source 104 may comprise a wavelength tunable laser source. In some implementations, the light source 104 can be a single mode laser that generates light having wavelengths within a laser bandwidth (e.g., a narrow bandwidth) centered at a laser wavelength. The laser wavelength can be from 400 nm to 600 nm, from 600 nm to 800 nm, from 800 nm to 1000 nm, from 1000 nm to 1200 nm, from 1200 nm to 1400 nm, from 1600 nm to 1800 nm, 1800 nm to 2000 nm, from 2000 nm to 2500 nm, from 2500 nm to 3000 nm, from 3000 nm to 4000 nm, from 4000 nm to 5000 nm, or any ranges formed by these values or larger or smaller. The laser bandwidth can be from 1 KHz to 500 KHz, from 500 KHz to 1 MHz, from 1 MHz to 5 MHz, from 5 MHz to 10 MHz, from 10 MHz to 100 MHZ, from 100 MHz to 1 GHz, from 1 GHz to 10 GHz, or any ranges formed by these values or larger or smaller. In some implementations, the light source 104 may comprise an array of laser sources (e.g., a laser array) having different wavelengths. An individual laser source of the laser array can be a single mode laser. In some cases, at least two individual laser sources of the laser array can have different laser wavelengths. In some cases, individual laser sources of the laser array can be wavelength tunable lasers. In some examples, the wavelength of an individual laser source may be tuned to be different from the wavelengths of other laser sources in the laser array.

The optical coupling section (or region) 106 may be configured to distribute and/or couple one or more light beams generated by the light source 104 to the optical array 102 (e.g., to the respective individual optical gain sections). In some cases, the optical coupling section 106 may include an optical distribution section (or region) configured to distribute light received from the light source 104 among the individual elements (e.g., optical amplifier, laser, or MOPA elements) of the optical array 102, e.g., by dividing a light beam received from the light source 104 into N light beams where N can be a number of elements in the optical array 102. In various implementations, the N light beams may have different or substantially equal optical powers or intensities. Additionally or alternatively, the optical coupling section 106 may include a beam forming section (or region) that changes a cross-sectional area and/or shape of the individual light beams received from the light source 104 or the optical distribution section to increase portions of the individual light beams that are coupled to the respective elements of the optical array 102. In some examples, the distribution section may include a 1×N directional coupler or optical power divider and the beam forming section may comprise a lens array. The optical coupling section 106 may comprise fiber optic devices, free-space optical devices, on-chip optical devices, or a combination thereof. In some cases, the one or both distribution section and the beam forming section of the optical coupling section 106 may comprise a photonic circuit (e.g., a monolithically fabricated waveguide network). One or both the optical coupling section 106 and the optical array 102 can be monolithically fabricated on a single chip or two separate chips.

The beam transforming section 108 may be configured to transform a wavefront and/or direction of propagation of the individual light beams output by the optical array 102. In some cases, the beam transforming section 108 may collimate individual light beams output by the optical array 102 to generate an array of collimated beams. In some cases, the beam transforming section 108 may redirect the individual light beams toward a target region or point. In various implementations, the beam transforming section 108 may comprise a single (e.g., a lens) or a plurality of optical elements (e.g., a lens array).

The beam combining section 112 may be configured to combine the individual light beams output by the optical array 102 or received from the beam transforming section 108 to generate the high brightness light beam 114. In some cases, beam combining may comprise superimposing the light fields associated with the individual light beams having substantially the same center wavelength to generate a single wavelength high brightness light beam possibly via constructive interference. In some cases, beam combining may comprise redirecting and reshaping the light beams to generate a high brightness multi-wavelength light beam.

In some such implementations, the relative phases of individual light beams output by individual optical gain sections of the optical array 102 may stay substantially constant over time. In some such cases, the individual light beams may be actively or passively phase locked. In some such cases, the relative phases of individual light beams that are phase locked may be adjusted to increase the brightness, optical power, radiance, beam quality or any combination thereof of the combined light beam 114 generated by, e.g., overplaying, interfering, and/or superimposing the individual light beams and/or the corresponding optical fields.

In some implementations, the optical system 100 may include an optical array 102 comprising an array of optical amplifiers, a light source 104 configured to output a source light beam having a single wavelength, an optical coupling section (e.g., an optical coupler) 106 configured the divide and distribute light beam among the optical amplifiers of the optical array 102 for amplification. In some such implementations, individual phases of individual amplified light beams output by the optical array 102 may be linked to a phase of the source light beam causing the individual phases of individual amplified light beams to be locked to each other. In some cases, the optical path lengths from the light source 104 to the individual output ports of the optical amplifiers can be substantially equal (and/or can be controlled to be equal or substantially equal or within 20%, 15%, 10%, 5%, 2%, 1% or any range formed by any of these values), resulting in a small (negligible, or substantially zero or less than 20%, 15%, 10%, 5%, 2%, 1% or any range formed by any of these values) phase difference between individual amplified light beams. In these cases, the resulting combined light beam 114 may have a high brightness (high radiance) due to constructive interference between the individual amplified light beams. In some examples, optical coupling section and the optical array 102 may be configured to provide substantially equal optical paths for the individual amplified light beams or optical paths with difference less than 20%, 15%, 10%, 5%, 2%, 1% or any range formed by any of these values. Additionally or alternatively, the optical coupling section 106 and/or the optical array 102 may provide adjustable optical paths for the individual amplified light beams and a control system may control the adjustable optical paths (passively or actively) to be substantially equal or within 20%, 15%, 10%, 5%, 2%, 1% or any range formed by any of these values. In some cases, the beam transforming section 108, and the beam combining section 112 may be configured to provide substantially equal optical paths (or optical paths within 20%, 15%, 10%, 5%, 2%, 1% or any range formed by any of these values) for the individual amplified light beams received from the individual output ports of optical array 102 (output port of the optical amplifiers) to a spatial location where the corresponding light beams (or optical field) are superimposed, overlapped, and/or interfered to generate the combined light beam 114 (the high brightness output light beam).

In some implementations, the optical system 100 may include an optical array 102 comprising an array of lasers or MOPAs, a light source 104 configured to output one or more source light beams having a single wavelength, and an optical coupling section 106 configured to couple the one or more source light beams to the optical amplifiers of the optical array 102 for amplification. In some cases, the optical coupling section 106 may divide a source light beam to a plurality of source light beams and couple the plurality of source light beams to the optical amplifiers of the optical array 102 for amplification.

In some such implementations, individual phases of individual light beams generated by individual lasers or MOPAs may be locked to a phase of the source light beam (e.g., through injection locking), causing the individual phases of the light beams generated by the lasers or MOPAs to be locked to each other. In some cases, the optical path lengths from the light source 104 to the individual back reflectors of the lasers or MOPAs can be substantially equal (or can be controlled to be substantially equal or within 20%, 15%, 10%, 5%, 2%, 1% or any range formed by any of these values) resulting in a very small phase difference (e.g., within 20%, 15%, 10%, 5%, 2%, 1% or any range formed by any of these values) between individual light beams generated by the lasers or MOPAs and causing generation of a high brightness output beam 114 (due to constructive interference between the individual light beams). In some examples, the optical coupling section 106 may be configured to provide substantially equal optical paths (or within 20%, 15%, 10%, 5%, 2%, 1% or any range formed by any of these values) between the light source 104 and the individual back reflectors of the lasers or MOPAs in optical array. Additionally or alternatively, the optical coupling section 106 may provide adjustable optical paths for the individual light beams provided to the optical array 102 and a control system may control the adjustable optical paths (passively or actively) to be substantially equal or within 20%, 15%, 10%, 5%, 2%, 1% or any range formed by any of these values. In some cases, the beam transforming section 108, and the beam combining section 112 may be configured to provide substantially equal optical paths or optical paths within 20%, 15%, 10%, 5%, 2%, 1% or any range formed by any of these values for the individual light beams generated by the lasers or MOPAs, from the individual output ports of the lasers or MOPAs to a spatial location where the corresponding optical field are superimposed to generate the high brightness optical output beam 114.

In some implementations, the light source 104 may generate a plurality of phase locked light beams having substantially the same wavelengths (or center wavelengths) and provide them to the individual optical gain sections of the optical array 102 via the optical coupling section 106. In some examples, the light source 104 may comprise a plurality of passively phase locked lasers (e.g., evanescently coupled lasers). In some cases, the light source 104 may comprise a plurality of actively phase locked lasers (e.g., using electronic control). The optical array 102 may amplify the individual phase locked light beams received from the light source 104 and output an array of amplified light beams that are combined to generate the combined light beam 114 (e.g., a single wavelength high brightness light beam). In some cases, the phases of the individual optical gain sections in the optical array 102 may be further controlled by a feedback section 110 to reduce a phase difference between the individual phase-locked light beams. The feedback section 110 may comprise one or more photodetectors configured to provide detector signals indicative of a distribution of optical power and/or intensity of light incident on the feedback section 110 (e.g., light received from the optical array 102 or the beam transforming section 108). In some examples, the feedback section 110 may include at least two detectors or detector elements that generate two signals indicative of the optical power or the intensity of light incident on the feedback section 110 at or near two different spatial locations (e.g., two different locations on a plane perpendicular to a direction of propagation of light).

In some implementations, the light source 104 may generate a plurality of individual light beams having different wavelengths and provide them to the individual optical gain sections of the optical array 102 via the optical coupling section 106. The optical array 102 may individually amplify these light beams and output an array of amplified light beams having different wavelengths. In these implementations, the beam combining section 112 may comprise a diffractive grating and the beam transforming section 108 may redirect the light beams output by the optical array 102 to the diffractive grating to generate a single multi-wavelength beam (e.g., a high brightness combined beam). In some such implementations, the phases of the individual optical gain sections in the optical array 102 may not need to be controlled as the light beams are not coherently combined.

In some cases, the optical array 102 may comprise a plurality of optical gain sections included in an external cavity configuration to form a plurality of external cavity lasers that generate a plurality of the light beams having different wavelengths. In some such cases, the beam combining section 112 may, for example, comprise a diffraction grating and an output coupler that receives light beams diffracted by the diffraction grating and serves as a common reflector for the plurality of external cavity lasers. The diffraction grating may cause the reflected light from the output coupler to be diffracted such that diffracted light beams having different center wavelengths are fed back into different optical gain sections. The center wavelength of an individual external cavity laser can be determined by the angle of incidence between the diffraction grating and the light beam output by the external cavity laser. In some cases, regions of a back facet of the optical array 102 may serve as back reflectors for the plurality of external cavity lasers. In some implementations, the plurality of the light beams are combined by the diffraction grating, as they are sustained in the individual external cavities, and the output coupler outputs the resulting high brightness multi-wavelength light beam.

In some cases, the optical array 102 may comprise individual tunable lasers that generate the individual light beams having different wavelengths. For example, an optical gain region of an optical gain section may be included in a tunable cavity. The tunable cavity may comprise thermo-optically, acousto-optically, magneto-optically, or electro-optically tunable elements (e.g., mirrors) that allow tuning a resonant wavelength of the cavity within the gain bandwidth of the corresponding optical gain region. In some examples, an individual optical gain section may comprise a tunable laser formed using a non-flared optical gain region and flared optical gain region that amplifies the light received from the tunable laser.

FIG. 1B is a block diagram illustrating another example optical system 101 for generating a combined light beam 114 by combining light beams generated by an optical array 102 comprising individual optical gain sections at least partially included in an external cavity configuration, where at least one optical gain section comprises a flared optical gain region.

In some implementations, the optical system 101 may comprise the optical array 102 and a back cavity coupler region 116a that is configured to couple light amplified by an individual optical gain section to at least one other individual optical gain section. In some cases, the individual optical gain sections may comprise a front reflector and the back cavity coupler region 116a may couple light amplified by an individual optical gain section to at least a portion of other optical gain sections of the optical array 102 to form a super-mode cavity with the front reflectors of the individual optical gain sections. The super-mode cavity and the optical gain regions therein may form a plurality of external cavity lasers that generate a plurality of the substantially phase-locked light beams. In some cases, a light beam generated by an external cavity laser may be further amplified by an optical gain region (e.g., a flared optical region) of the corresponding optical gain section (e.g., located outside the super-mode cavity).

In some implementations, the optical system 101 may comprise the optical array 102 and a front cavity coupler region 116b that is configured to couple light amplified by an individual optical gain section to at least one other individual optical gain section. In some cases, the individual optical gain sections may comprise a back reflector and the front cavity coupler region 116b may couple light amplified by an individual optical gain section to at least a portion of other optical gain sections of the optical array 102 to form a super-mode cavity with the back reflectors of the individual optical gain sections. The super-mode cavity and the optical gain regions therein may form a plurality of external cavity lasers that generate a plurality of the substantially phase-locked light beams.

In some implementations, the optical system 101 may comprise the optical array 102 and a back cavity coupler region 116a that comprises an array of evanescently coupled waveguides. In some cases, an individual laser of the back cavity coupler region 116a may comprise an optical gain region within a cavity. In some such cases, the light generated by an individual laser may be provided to an optical gain section of the optical array 102 for further amplification. In some cases, an individual waveguide of the back cavity coupler region 116a may comprise a back reflector. In some such cases, an optical gain section of the optical array 102 may comprise a front reflector and can be optically connected to the individual waveguides to form a laser cavity between the front reflector of the optical gain section and the back reflector of the back cavity coupler region 116a. Since the laser sources formed with the back cavity coupler region 116a and the optical array 102 include evanescently coupled waveguides, the light beams generated by these laser sources can be phase-locked. As such, the optical system 101 that comprises the optical array 102 and the back cavity coupler region 116a having of evanescently coupled waveguides generates a plurality of phased locked light beams output by the optical array 102. When combined, these phase-locked light beams can generate a high brightness beam 114. In some cases, the phases of the individual optical gain sections in the optical array 102 may be further controlled by a feedback section 110 to reduce a phase difference between the individual phase-locked light beams.

In some cases, the optical system 101 may further include a beam transforming section 108, that transforms (e.g., collimates) the plurality of light beams received from the optical array 102, and a beam combining section 112 that coherently combines the light beams received from the beam transforming section 108. In some cases, the optical system 101 may comprise a feedback section 110 having features similar to the feedback section 110 described above with respect to the optical system 100. The feedback section 110 may improve the phase locking between the light beams generated by the individual lasers of the back cavity coupler region 116a, or the external cavity lasers, by controlling, for example, an optical gain region or non-flared region of the corresponding optical gain sections and/or lasers via individual control signals as described above with respect to the optical system 100.

In any one of the configurations described with respect to the optical system 100, or optical system 101, the feedback section 110 placed in a front side or output side of the optical array 102 (closer to the flared optical gain regions) may be used to actively adjust a property of the light beams output by the optical array based on a measured optical power, optical intensity, optical power distribution, optical intensity distribution, or other parameters of light output by the optical array 102 or any combination thereof. In various implementations, the feedback section 110 may be placed between the optical array 102 and the beam transforming section 108, between transforming section 108 and the beam combining section 112, or after the beam combining section 112 or possibly elsewhere.

The feedback section 110 may comprise an optical element (e.g., a partial reflector) that couples at least a portion of the light received, for example, from the optical array 102, the beam transforming section 108, or the front cavity coupler region 116b, to at least one photodetector that generates at least one detector signal indicative of the optical power or intensity of the received portion of light. The received portion of light may comprise light output by one or more laser or amplifier elements of the optical array 102. For example, the photodetector may receive light output by two adjacent laser or optical amplifier elements or light output by a subset of the laser or optical amplifier elements.

In some examples, the feedback section 110 may comprise a plurality of photodetectors or photodetector elements (e.g., a detector array, a charge coupled detector, or the like) where an individual photodetector element or a group of photodetector elements detect different portions of light output by different laser or amplifier elements or different groups of laser or amplifier elements. As such, the plurality of photodetectors detectors may generate a plurality of photodetector signals indicative of optical power or optical intensity of light output by different laser or amplifier elements.

In some examples, a photodetector of the feedback section 110 may use frequency tagging to identify one or more laser or optical amplifier elements of the optical array 102 from which a portion of light is received and generate a detector signal indicative of optical power or optical intensity of light output by the identified laser or optical amplifier elements.

In various implementations, the feedback section 110 may include different designs, and arrangements, that may be used to generate detector signals indicative of optical power or intensity of light received from different laser and amplifier elements of the optical array 102.

The feedback section 110 may further include an electronic circuitry configured to use the detector signals to generate control signals 111 and provide the control signals to optical amplifiers or laser elements of the optical array 102.

The feedback section 110 further includes electronic circuitry configured to generate control signals 111 based on one or more detector signals (e.g., a photocurrents) received from the one or more photodetectors. In some examples, a control signal may comprise an electrical signal (e.g., an electrical current or voltage). In some cases, an individual control signal may be provided to an individual element or section (optical amplifier, laser, passive waveguide, gain section or region) of the optical array 102. In some cases, an individual control signal may be provided to two or more elements or sections. In some cases, an individual control signal may be provided to an individual optical gain section to control a phase or a power of light generated or amplified by the optical gain section, e.g., by controlling an optical property (e.g., refractive index, or optical gain) of at least a region of the optical gain section. In some examples, an individual control signal may be provided to one or both of a non-flared and a flared optical gain region of an individual optical gain section via one or two electrodes. In some examples, an individual control signal may be provided to an optical gain section of a laser and/or optical gain section of an amplifier. In some cases, an individual control signal may be provided to a passive portion of a waveguide region that does not provide optical gain is optically coupled to an optical gain section. A control signal may control the phase of light passing through a region of the optical gain section (flared or non-flared) or the passive waveguide portion via thermo-optical, electro-optical effect, acousto-optic, magneto-optic, or other effects. For example, the control signal may control a current or voltage provided to an electro-thermal element (e.g., a resistive heater) near the region or to an electro-optically active portion of the region. In some examples, a control signal may control the phase and/or power of light passing through an active region of the corresponding optical gain section by controlling a current or voltage provided to the active region and in some cases thereby the optical gain generated in that region.

In some implementations, the individual control signals may be configured to control individual phases of light beams generated by, or amplified in, the optical array 102 to increase the optical power detected by the photodetector, and thereby the power of the combined light beam 114 generated by the optical system 100, 101, e.g., by reducing a phase difference among the individual light beams output by the optical array 102.

FIG. 1C illustrates various lasers, optical amplifiers, and MOPA designs that may utilize the optical array 102 of the optical system 100 or 101. In various implementations, the design may include at least a first waveguide region 122 (also referred to as the first waveguide region) that can provide optical gain upon being pumped by an injection current.

The first waveguide region 122 extends from an input port to an output port in a longitudinal direction (e.g., z-direction) and can comprise a flared optical gain region. In some examples, the flared optical gain region may have a lateral width, in a lateral direction (e.g., x-direction) perpendicular to the longitudinal direction, which increases (linearly or non-linearly) from the input port to the output port. In some cases, the first waveguide region 122 can be flared waveguide region with a lateral width that increases (linearly or non-linearly) from the input port to the output port. In some other cases, the waveguide region 122 can be non-flared and its lateral width may remain constant from the input port to the output port. Other designs are possible. In some implementations, for a given operational wavelength of the optical array 102, the lateral width of the first waveguide region 122 can be large enough to support propagation of at least one high order lateral optical mode. In various implementations, a pumped region (e.g., an optical gain region) of the first waveguide region 122 may be configured to provide more optical gain to a fundamental lateral mode compared to higher order lateral modes. For example, a pumped region of the first waveguide region 122 can be flared (e.g., a flared optical gain region). In some cases, a pumped region of a non-flared waveguide region can be flared. The pumped region may be a region receiving injection current from a patterned (e.g., flared) electrode and/or via a patterned (e.g., flared) dielectric layer. In some designs, a flared electrode or dielectric layer pumped region may have a lateral width (or an average lateral width) that increases (linearly or non-linearly) from the input port to the output port of the first waveguide region 122. In some cases, a flared electrode can be a flared segmented electrode where at least some of different segments are configured to provide different injection current/voltage to corresponding pumped segments of the first waveguide region 122. In some cases, a flared electrode can be a top or bottom electrode.

In some cases, a flared electrode can be a flared patterned electrode 125 configured to generate an injection distribution across the first waveguide region 122 that selectively amplifies a fundamental lateral mode of the first waveguide region 122. For example, a lateral width of the flared patterned electrode 125 may undulate along a longitudinal direction (parallel to the direction of propagation of light in the optical device), while its average lateral width increases along the longitudinal direction. In some implementations, the flared patterned electrode 125 may comprise electrically isolated electrode segments.

In some examples, the first waveguide region 122 may comprise any shape having a lateral width (e.g., parallel to x-axis) that varies or undulates along the longitudinal direction (e.g., parallel to z-axis).

Additionally, some lasers, optical amplifiers, and MOPAs included in the optical array 102, may comprise a second waveguide region 123 that is not flared or does not include a flared pumped region.

The second optical waveguide region 123 may be optically connected to the input port of the first waveguide region 122. For example, the second waveguide region 123 may extend from a first end to a second end, and the first waveguide region 122 may extend from the second end to a third end (output port) where the second end or the interface between the first and second waveguide regions 122, 123, is the input port of the first waveguide region 122. The second waveguide region 123 can be an active waveguide capable of providing optical gain, or a passive waveguide with no optical gain. In some cases, a reflector may be disposed at the first end of the second waveguide region 123, at the interface between the first and the second waveguide regions 122, 123, or at the output port of the first waveguide region 122 or a combination of these. In some cases, an optical path length of at least a portion of the first waveguide region 122 and/or the second waveguide region 121 can be tunable. For example, the first and/or the second waveguide regions 122, 123 may include a phase section. A phase section can be a section that controls (e.g., thermo-optically or electro-optically) the optical path length of light passing through the phase section based on a control signal received, e.g., from the feedback section 110. The phase section may include an electrode (e.g., disposed above or near the waveguide region), used to control the optical path length. In some example, the electrode can be electrically connected to the feedback section 110.

The optical devices 120 and 126 can be optical amplifiers. In some designs, the optical amplifier 120 includes a first waveguide region 122 that provides gain and a second waveguide region 123 that may or may not provide optical gain. In some designs, the optical amplifier 126 includes a first waveguide region 122 that provides gain, a second waveguide region 123 that may or may not provide optical gain, and a third waveguide region 124 that provides optical gain (upon being pumped). In some implementations, the first waveguide region 122 can be a flared waveguide region or include a flared optical gain region, and the second waveguide region 123 is a non-flared waveguide region. In some cases, the second waveguide region 123 comprises an optical pre-amplifier and the first 122 and possibly the third 124 waveguide regions comprise power optical amplifiers. In some designs, the optical amplifiers 120, 126, may not include the second waveguide region 123 or the third waveguide region 124.

The optical device 128 can be a MOPA. The MOPA 128 may include a first waveguide region 122 and a second waveguide region 123 that both provide optical gain upon being pumped. The MOPA 128 further includes a first reflector 130 disposed at the first end of the second waveguide region 123, and a second reflector 132 at the interface between the first and the second waveguide regions 122, 123. The first reflector 130, the second waveguide region 123, and the second reflector 132 form a laser (e.g., a master oscillator) and the first waveguide region 122 serves as an optical amplifier.

The optical device 133 can be a flared laser. The flared laser 133 includes a first waveguide region 122 a first reflector 130 and a second reflector 132 disposed at the input and output ports of the first waveguide region 122, respectively.

The flared laser 134 includes a first waveguide region 122 that provides optical gain (upon being pumped), and a second waveguide region 123 that may or may not provide optical gain. The flared laser 134 further includes a first reflector 130 disposed at the first end of the second waveguide region 123, and a second reflector 132 disposed at the output port of the first waveguide region 122. In some cases, the flared laser 134 may be configured to sustain and amplify light having a fundamental lateral mode profile by filtering out the higher order lateral modes, using a selective optical loss mechanism that reduces a power of the high order lateral modes along the cavity formed between the first and the second reflectors 130, 132. The MOPA 140 includes the flared laser 134 optically connected to a non-flared optical amplifier 124.

In various implementations, the first waveguide region 122 of any of the amplifiers, lasers, or MOPAs described above may comprise patterned, segmented, or patterned and segmented electrode. A patterned electrode can have a lateral width that changes (e.g., undulates, increases, or decreases) along the longitudinal direction. A flared electrode can have a lateral width or an average width that increases (e.g., monotonically) in a longitudinal direction (parallel to the direction of propagation of light). A segmented electrode may comprise a plurality of longitudinal or lateral electrode segments, or both. As such a patterned electrode can be a patterned flared electrode, can be a patterned segmented electrode, or a patterned, flared and segmented electrode.

In various implementations, the first waveguide region 122 of any of the amplifiers, lasers, or MOPAs described above may comprise patterned, segmented, or patterned and segmented electrode. A patterned electrode can have a lateral with that changes (e.g., undulates, increase, or decreases) along the longitudinal direction. A flared electrode can have a lateral width or an average with that increases (e.g., monotonically) in a longitudinal direction (parallel to the direction of propagation of light). A segmented electrode may comprise a plurality of longitudinal or lateral electrode segments, or both. As such a patterned electrode can be a patterned flared electrode, can be a patterned segmented electrode, or a patterned, flared and segmented electrode.

Additionally or alternatively, the first waveguide region 122 may comprise a patterned, segmented, or patterned and segmented current control layer. In various examples, a patterned electrode or current control layer may comprise any shape including a flared shape having a lateral width or an average lateral width that increases along the longitudinal direction, a shape having a lateral width undulating along the longitudinal direction, or other shapes. A current control layer may comprise a dielectric layer or ion implanted layer, and/or a conductive layer configured to provide a current distribution across an optical gain layer of the first waveguide region 122 such that the optical gain layer selectively provides more gain to the fundamental lateral mode of the first waveguide region 122 compared to higher order lateral modes supported by the first waveguide region 122. Examples of lasers, amplifiers, and MOPAs having flared optical gain regions with flared electrodes are discussed in U.S. patent application Ser. No. 17/806,460 (Attorney Docket No. FREDOM.026A2) filed on Jun. 10, 2022 published as U.S. Publication No. 2023/0023686 A1, which is hereby incorporated by reference herein in its entirety. In various implementations, the optical array 102 may include any of the lasers, amplifiers, and MOPA designs described in U.S. Publication No. 2023/0023686 A1.

FIG. 1D illustrates a cross-section of a flared optical gain region 150 (or section) generated by a patterned (tailored) top electrode 153. The cross-sectional profile of the flared optical gain region 150 shows the tailored (e.g. top) electrode 153 and a flared optical gain profile 170, and the optical intensity profile of a guided optical wave propagating and being amplified in the flared optical gain region 150. The tailored top electrode 153 is disposed on top of a flared waveguide 151 (or a non-flared waveguide 152) and extends from the input port 154 to the output port 156 along the longitudinal direction (e.g., parallel to z-axis). This tailored top electrode 153 has a first end closer to the input port 154 and a second end closer to the output port 156. In various implementations, the tailored top electrode 153 has a length, and the first end of the top electrode is within 20%, 10%, 5%, 3%, 1% or 0.5% of the length from the input port or any range between any of these percentages or may be closer or farther. Similarly, in some implementations, the second end of the tailored top electrode 153 is within 20%, 10%, 5%, 3%, 1%, 0.5% of the length from the output port or any range between any of these percentages or may be closer or farther. The tailored top electrode 153 also has first and second lateral edges. In the example shown the first lateral edge may be the lateral edge located above z-axis (positive x region) and the second edge may be the lateral edge located below z-axis (negative x region). The electrode (e.g., the top electrode) comprises a conductive layer and is disposed with respect to the active waveguide to apply an electrical power to said active waveguide. In some cases, the tailored top electrode 153 (e.g., a tailored top electrode) may cover only a portion of the flared optical gain region 150 along the longitudinal direction so as to tailor the current injected into the active layer. In some implementations, such as shown in FIG. 1D, the tailored top electrode 153 has a width extending in the lateral direction (parallel to x-axis) between the first and second lateral edges that that increases and decreases multiple times with position along the longitudinal direction. In some implementations, such as shown in FIG. 1D, one or both of the first and second lateral edges undulates in the lateral direction. In some implementations, such as shown in FIG. 1D, the electrode increases in lateral width on average from the first end to said second end of the electrode or a portion of the length from the input to the output such as 50%, 60%, 75%, 80%, 90%, 95% or any range formed by any of these values. In various implementations, the lateral width of the electrode 153 increases and decreases varying between a plurality of lower bound widths (a plurality of local minima) and a plurality of upper bound widths (a plurality of local maxima), increasing with longitudinal directions (e.g., along ±z directions) from the lower bound widths and decreasing with longitudinal direction (e.g., along ±z directions) from the upper bound widths. The result is a plurality of protrusions on the lateral edge of the electrode extending in the lateral direction. In various implementations, these protrusions can be on one or both sides of the electrode. The variations in said lateral width of the electrode 153 averaged over a distance in the longitudinal direction, that includes multiple lower bound widths (local minima) and multiple upper bound widths (local maxima) or multiple protrusions (e.g., 3, 5, 10, 15, 20, 30 on one side), produces an average width that increases (possibly progressively increases or continuously increase) with longitudinal direction from the first end to the second end of said electrode along most of the length of the electrode and/or from the input port 154 to the output port 156 or a portion of this length such at 50%, 75%, 90% or any range formed by any of these values. As shown in FIG. 1D, for example, the tailored top electrode 153 has a width W(z) in the lateral direction that alternatively changes along the longitudinal direction between a plurality of upper bound widths (e.g., 165a and 165b) and a plurality of lower bound widths (e.g., 166a and 166b). For example, the width of the tailored top electrode 153 changes from a first upper bound width 165a to a first lower bound width 166a, and from the first lower bound width 166a to a second upper bound width 165b. An upper bound width may be between 1.0 μm and 10 μm, 10 μm and 1000 μm, 1000 μm and 10000 μm. A lower bound width may be between 0.1 μm and 1 μm, 1 μm and 10 μm, 10 μm and 100 μm, 100 μm and 1000 μm, 1000 μm and 10000 μm or any range formed by any of these values or large or smaller.

In some cases, the upper bound widths (or local maxima) and the lower bound widths (or local minima) increase from the input port 154 to the output port 156. In some cases, the upper bound widths (or local maxima) increase, and the lower bound widths (or local minima) remain constant from the input port 154 to the output port 156. In some cases, an angle of the tailored electrode 153 associated with an average width of the tailored top electrode may be matched to the natural diffraction angle (ϕ) of a guided optical wave having a fundamental lateral mode profile (e.g., the fundamental guided optical wave). For example the angle of the tailored electrode 153 associated with an average width of the tailored top electrode may be within 20%, 50%, 100%, 250% or 500% to the natural diffraction angle (ϕ) of a guided optical wave having a fundamental lateral mode profile (e.g., the fundamental guided optical wave) or any range formed by any of these percentages or larger or smaller.

The width W(z) of the tailored top electrode 153 may change linearly or nonlinearly (e.g., sinusoidally, exponentially and the like) from an upper bound width (local maxima) to the subsequent lower bound width (local minima) or from a lower bound width (local minima) to the subsequent upper bound width (local maxima). In some examples, the shape of resulting tailored electrode between two consecutive lower bound widths may have a diamond like or triangular shape, a curved or wavy shape, or other shapes.

In some cases, the width of the tailored electrode may periodically vary along the longitudinal direction. In some such cases, a longitudinal distance between pairs of consecutive lower bound widths (or upper bound widths) may be equal to a period (also referred to as width variation period). The period can be between 0.1 μm and 1 μm, 1 μm and 10 μm, 10 μm and 100 μm, or 100 μm and 1000 μm or any range formed by any of these values or large or smaller.

In some cases, the variation of the width of the tailored top electrode along the longitudinal direction may be aperiodic. In some such cases, a longitudinal distance between positions at which sequential upper bound widths and lower bound widths occur may increase or decrease from the input port 154 to the output port 156. In some such cases, a longitudinal distance between positions at which sequential upper bound widths and lower bound widths occur may increase in a first portion and decrease in a second portion of the length of the active waveguide.

In some cases, the average width of the tailored electrode 153 may increase (possibly progressively or continuously) from a minimum average width at the input port 154 to a maximum average at the output port, where the average width corresponds to an average magnitude of the width calculated for at least one period of width variation or possibly more. The average width may for example, be determined over 3, 5, 10, 15, 20, 30 or more protrusions (local maxima) counted on one side of the electrode, or any range formed by any of these values or larger or smaller. The average width of the tailored electrode 153 may vary linearly or non-linearly from the minimum average width to the maximum average width.

In some cases, the average width of the tailored top electrode 153 may be substantially equal to the width of the guided optical wave (e.g., the FWHM of the corresponding optical intensity distribution in the lateral direction). In some cases, the average width of the tailored electrode 153 may change with a rate substantially equal to the rate at which the width of the guided optical wave (e.g., the fundamental optical wave) changes along the longitudinal direction.

With continued reference to FIG. 1D, in some cases, the width of the tailored electrode 153 may be defined by two half-width functions, W+_{1/2}(z) and W−_{1/2}(z) functions that quantify lateral distances between the first lateral edge (in the positive x region) and the second lateral edge (in the negative x region) of the tailored top electrode 153 and the centerline through the waveguide, a longitudinal axis of symmetry of the guided optical wave and/or the active waveguide (e.g., z-axis), respectively. In some cases, W+_{1/2}(z) and W−_{1/2}(z) may be different functions of z. In some cases, W+_{1/2}(z) and W−_{1/2}(z) may be substantially the same functions of z. In some such cases, the tailored top electrode 153 may be symmetric with respect to z-axis. In some such cases, W+_{1/2}(z) and/or W−_{1/2}(z), each may be bound by an upper bound margin and a lower bound margin. In some cases, W+_{1/2}(z) and/or W−_{1/2}(z) may be a piecewise functions of z. For example, the shape of the tailored electrode 153 may be different between a first pair of consecutive lower band widths and a second pair of consecutive lower bound widths. In some cases, W+_{1/2}(z) and/or W−_{1/2}(z) each may be a periodic function of z oscillating between the corresponding upper bound margin and lower bound margins. The upper bound margins and the lower bound margins may be linear or nonlinear functions of z. In some examples, the upper bound margins and the lower bound margins may be linear function of z having different slopes. In some examples, the upper bound margins may be a linear function of z and the lower bound margins may be constant (does not change with respect to z). In some cases, the characteristics of the corresponding W+_{1/2}(z) and/or W−_{1/2}(z) functions may be determined based at least in part on the thickness and/or physical properties (e.g., electrical, thermal and optical) of the top layer, gain layer and the bottom layer of the corresponding active waveguide. In the example shown, W+_{1/2}(z), that quantifies the lateral distance between the first lateral edge and the z-axis, is bound by the upper bound margin 165 and the lower bound margin 166 and oscillates between the upper bound margin 165 and the lower bound margin 166. In some cases, the upper bound margin 165 and/or the lower bound margin 166 can be a nonlinear function of z (e.g., an exponential or a square root function).

Similarly, the lateral edges of the tailored top electrode 153 include a plurality of points corresponding to said upper bound widths (local maxima) that intersect and are bounded by an upper boundary and a plurality of points corresponding to said lower bound widths (local minima) that intersect and are bounded by a lower boundary. In some implementations, an upper boundary comprises a first straight line having a first slope. In some implementations, a lower boundary comprises a second straight line having a second slope. In some implementations, the first and second slopes are different. In some cases, first slope is higher than said second slope. In other cases, the first slope is lower than the second slope. In some designs, though, the first and second slopes are equal. In some designs, the upper and/or lower boundaries are a non-linear and may be curved (e.g., quadratically, exponentially or otherwise). Various combinations are possible. For example, the upper boundary may be nonlinear while the lower boundary is linear, or vice versa. Or both the upper and lower boundaries may be linear or both may be non-linear. In some designs, the lower boundary comprises a straight line that is parallel to the length of said electrode. Other variations and configurations are possible.

In various embodiments, applying a voltage between the tailored top electrode 153 and a uniform bottom electrode may generate an injection current profile in the gain layer (in a plane parallel to x-z plane that passed through the middle of the gain layer) that is substantially matched, correlated or corresponds with the optical intensity profile of the guided optical wave (in the plane parallel to x-z plane passing through the middle of the gain layer).

In some cases, the flared optical gain region 150 may amplify a guided optical wave initially having a fundamental lateral mode profile 161 while maintaining its original lateral optical intensity distribution or close thereto. The lateral optical intensity distribution of the fundamental guided optical wave, at any position along longitudinal or z-axis (e.g., first position 158, second position 159 and third position 160), may be symmetric with respect to the longitudinal or z-axis and may have a bell-shaped distribution along x-axis or transverse direction. The peak of the corresponding bell shape distributions associated with different positions along the longitudinal axis or z-axis may overlap with the centerline of the waveguide or the z-axis. In some cases, a profile of the fundamental guided optical wave can be substantially similar to that of the flared optical gain profile 170. As shown in FIG. 1D, from the first position 158 to the second position 159, the initial lateral optical intensity distribution 161 changes to the lateral optical intensity distribution 162 with a larger under curve area but the same or essentially the same shape as the curve 161 (indicating that the optical power carried by the guided optical wave is increased but its lateral optical intensity distribution has not changed). Similarly, from the second position 159 to the third position 160, the lateral optical intensity distribution 162 changes to the lateral optical intensity distribution 163 with a larger under curve area but the same shape or essentially the same shape as the lateral optical intensity distribution 162.

In some cases, the initial guided optical wave may be generated by coupling an input optical wave having a fundamental lateral profile (e.g., a bell-shaped of Gaussian profile) to the flared optical gain region 150. In some other cases, the initial guided optical wave may be generated by coupling an input optical wave having an asymmetric optical intensity profile in the lateral direction (e.g., with respect to the longitudinal axis of symmetry of the optical amplifier or the z-axis). In some such cases, the initial guided optical wave may be the output of a single mode waveguide.

In some cases, the flared optical gain region 150 may amplify a guided optical wave initially having an asymmetric lateral mode profile (e.g., with respect to z-axis), while maintaining the corresponding lateral optical intensity distribution or close thereto as it propagates in the longitudinal direction along the flared optical gain region 150. For example, the lateral optical intensity distribution of the optical wave, at any position along longitudinal or z-axis (e.g., first position 158, second position 159 and third position 160), may be asymmetric with respect to the longitudinal or z-axis and may have one or more peak intensities located in the positive x region or negative x region. In some such cases, said initial guided optical wave may be generated by coupling an input optical wave having an asymmetric lateral optical intensity profile to the flared optical gain region 150.

In some implementations, the tailored electrode 153 may comprise a segmented electrode with multiple electrically isolated conductive segments. In some such designs, an electric potential of a separate segment relative to the electric potential of the bottom electrode and/or other segments may be controlled separately. Advantageously, independent control of the potential or voltages of the segments of the tailored electrode 153 may enable further control over the distribution of the injected current in the gain layer and therefore the distribution of the optical gain across the active waveguide. In some implementations, an electronic system (e.g., a current supply system) may be used to apply separate voltages to the separate electrically isolated segments. The separate voltages may be applied such that the injection current profile in a gain layer of the flared optical gain region 150 has a spatial distribution that varies across the lateral direction so as to suppress a lateral mode of the active waveguide. For example, the separate voltages applied by the electronic system may result in generation of a tailored injection current profile in the gain layer.

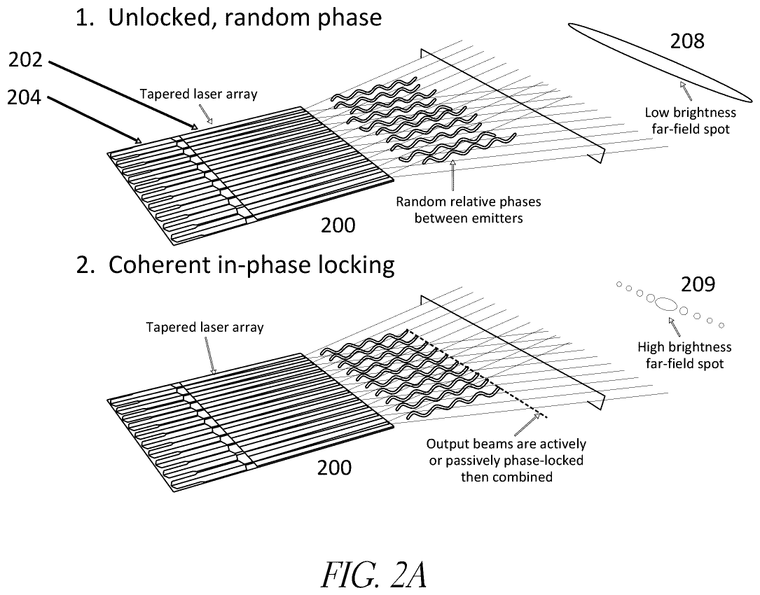

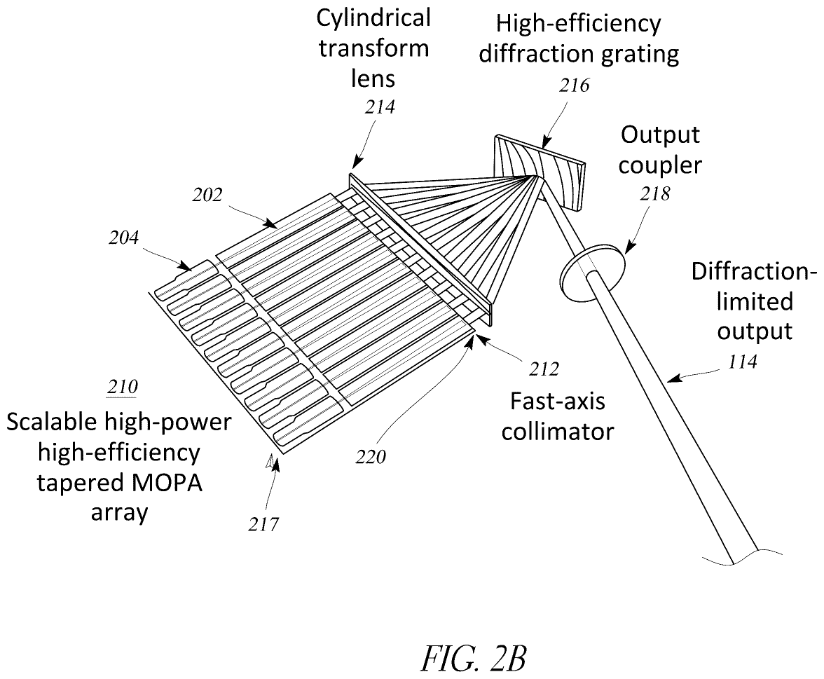

FIG. 2A schematically illustrates incoherent (top panel) and coherent (bottom panel) combination of light beams generated by an optical array 200. In some cases, the optical array 200 may comprise a plurality of light sources similar to the MOPA 128 or the flared laser 134 shown in FIG. 1C. In some examples, the optical array 200 may comprise a photonic chip having a first region 202 comprising an array of flared waveguide regions and a second region 204 comprising an array of non-flared waveguide regions where each pair of individual flared and non-flared waveguide regions form a MOPA or a flared laser. In some cases, at least the flared optical waveguide regions provide optical gain. The flared and non-flared waveguide regions of an individual MOPA may be pumped together or independently. When the individual MOPAs are not phase locked (top panel) the light beams generated by the optical array 200 may have random relative phase resulting in a far-filed pattern 208 having low brightness. When the individual MOPAs are phase locked (bottom panel), e.g., by actively controlling the flared and/or non-flared waveguide regions, the relative phases of light beams generated by the optical array 200 may be locked resulting in a far-field pattern 209 having a high brightness region.

FIG. 2B schematically illustrates an optical system for generating a high brightness multi-wavelength beam by spectrally combining light beams generated by a plurality of laser sources having flared (tapered) optical gain regions. In some cases, such optical system may include an optical array 210, a beam transforming section (e.g., comprising a collimator 212 and a cylindrical lens 214), a grating 216 (e.g., a high efficiency grating), and an output coupler 218. The optical array 210 may comprise a plurality of optical gain sections having flared optical gain regions. In some examples, the optical array 210 can be a monolithically fabricated photonic chip having a first facet 217 and a second facet 220 from which a plurality of light beams having different wavelengths are output. In some examples, the optical array 210 may comprise a scalable high efficiency tapered MOPA array. The collimator 212 may positioned at the second facet 220 and configured to collimate the light beams output by the optical array 210 (e.g., along a fast-axis of the corresponding waveguides). The cylindrical lens 214 may be positioned between the collimator 212 and the grating 216, and configured to redirect the collimated light beams received from the collimator 212 toward a common region of the grating 216. The grating 216 may be configured to diffract the collimated light beams, having different wavelengths, to a common direction and spatially overlap them to generate a high brightness multi-wavelength light beam 114 output via the output coupler 218.

The optical array or photonic chip 210 may have a first region 202 comprising an array of optically passive regions (having no optical gain)) or non-flared optical gain regions, and a second region 204 comprising an array of flared optical regions. In some cases, the first region 202 may comprise an array of non-flared waveguides and the second waveguide region 203 may comprise an array of flared waveguide regions. In some examples, the second region 204 may comprise an array of non-flared waveguide regions having flared optical gain regions.

In one implementation, a pair of individual flared and non-flared waveguide regions form an optical amplifier similar to the optical amplifier 120 having a non-flared region (e.g., the second waveguide region 123) and a flared region (e.g., the first waveguide region 122). Additionally, a reflector may be disposed at a first end of the non-flared region 123 (away from the interface between the non-flared and flared regions). At least the flared region 122 may provide optical gain upon being electrically pumped via electrode (e.g., a flared electrode, a flared and patterned electrode, or a flared, patterned and segmented electrode).

In some examples, the first facet 217 may comprise a highly reflective coated facet and the first reflector of an individual optical amplifier may be a region of coated facet of the optical array 210. An external laser cavity may be formed between the reflector of an individual optical amplifier and the output coupler 218, the output coupler 218 serving as a common front reflector for a plurality of external cavity lasers. The output coupler 218 may have a reflective surface having some reflectivity within an optical gain bandwidth of the optical amplifiers. The collimator 212, cylindrical lens 214 and grating 216 may be configured to direct light having different wavelengths back and forth between the output coupler 218 and the reflectors of different optical amplifiers. As such, an individual external cavity laser may sustain and generate light having a wavelength different than a wavelength of light generated and sustained by other external cavity lasers. The reflector of an individual optical amplifier may have high reflectivity at a wavelength sustained between the reflector and the output coupler 218, or a high reflectivity within the optical gain bandwidth of the optical amplifier. The plurality of external cavity lasers generates the plurality of the light beams having different wavelengths.

In another implementation, each pair of individual flared and non-flared waveguide regions of the optical array 210 may form a MOPA similar to MOPA 128 or a laser similar to the laser 134 comprising a non-flared region 123, a flared region 122, a back reflector 130, and a front reflector 132. In such implementation, the optical array 210 may comprise a plurality of individual lasers (each having a flared optical gain region). The front reflector 132 or the back reflector 130 of an individual laser may be configured to have a high reflection within a narrow bandwidth centered at laser wavelength different from the laser wavelengths of other lasers of the optical array 210. In some examples, the front reflector 132 or the back reflector 130 of a laser of the optical array 210 may comprise a tunable reflector having a tunable (e.g., thermally or electrically tunable) spectral reflectance. In various examples, the front reflector 132 or the back reflector 130 of a laser of the optical array 210 may comprise a Bragg reflector or a comb reflector (e.g., a Sampled Grating Distributed Bragg Reflector or SGDBR).

In some cases, a 4F optical imaging system may be placed between the grating 216 and the output coupler 218 serving as an optical relay between the grating 216 and the output coupler 218. In some examples, the 4F optical imaging system may comprise two positive power (e.g., convex) lenses with the input plane located at a first focal length of the first lens before the first lens and the output plane located at a second focal length of the second lens after the second lens. The magnification of the 4F optical imaging system can be equal to the ratio between the second and the first focal lengths.

In various implementations described herein, waveguide regions, reflectors, and phase control regions may be disposed on a substrate with epitaxial layers of doped and/or undoped semiconductor material thereon. A waveguide region can be formed from variety of semiconductor materials including but not limited to III-V semiconductor materials such as InP, GaAs, AlGaAs, InGaAs, AlInGaAs, InGaAsP, InAlAsP, or other compound semiconductor materials including but not limited to GaN, InAsSb, InSb, PbSe, PbTe, or any combination of these materials.

In various implementations described herein, reflectors disposed along a passive or active waveguide region of an optical array (e.g., optical array 102, 200, 210) may comprise a Bragg reflector or a comb reflector (e.g., a Sampled Grating Distributed Bragg Reflector or SGDBR).

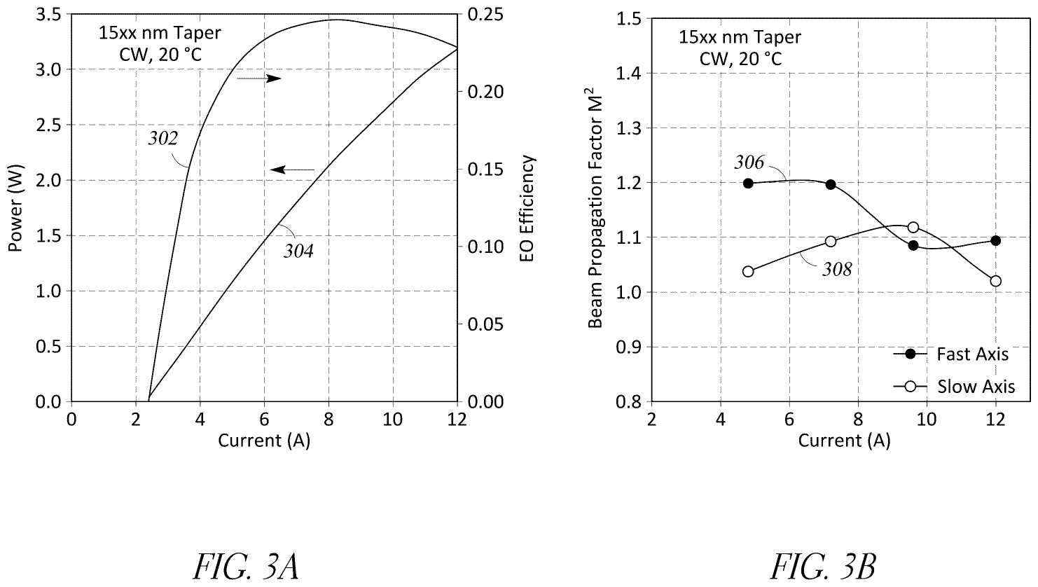

FIG. 3A shows measured optical output power 304 and efficiency 302 of an example MOPA, having an architecture similar to MOPA 128, plotted as a function of injection current (A). FIG. 3B shows the measured beam propagation factor (M²) of light beam generated by the example MOPA along the slow-axis 306 and fast-axis 308 of the MOPA, plotted against injection current. The measured data show that such MOPA, a MOPA having a flared optical gain region, can generate light beams having optical powers in excess of 3 Watts and still maintain a beam propagation factor (M²) less than 1.3, indicating that this MOPA can potentially generate high power optical beams having better quality (smaller M²) than light beams generated by conventional MOPAs having the same level of optical power.

In some implementations, M² of a light beam output by an individual light source (e.g., laser, or a MOPA) or optical amplifier of the optical array 102 along a fast-axis of the light source (or the optical amplifier), can be within 20%, 15%, 10%, 5%, 2% of 1 or substantially equal to or equal to 1 or any range formed by any of these values or possible larger. In various implementations, M² of the individual light beam along the slow-axis of the light source can be from 1 to 2. Accordingly BPP of the individual light beam, along the slow-axis, can be from 0.3 to 1.5 mm-mrad when the wavelength of the light beam is from 980 to 1550 nm.

In some cases, the optical output power of a light beam output by an individual light source (e.g., laser, or a MOPA) can be from 1 to 5 Watts, from 5 to 10 Watts, from 10 to 15 Watts, from 15 to 20 Watts, from 20 to 30 Watts, from 30 to 40 Watts, from 40 to 50 Watts, or any range formed by these values, or larger or smaller values.

In some cases, when M² of an individual light beam output by an individual light source (e.g., laser, or a MOPA) is from 1 to 3, along the slow-axis, the radiance of the individual light beam can be from 0.5 to 1 W/μsr·mm², from 1 to 5 W/μsr·mm², from 5 to 10 W/μsr·mm², from 10 to 50 W/μsr·mm², from 50 to 100 W/μsr·mm², from 100 to 200 W/μsr·mm², from 200 to 300 W/μsr·mm², from 300 to 400 W/μsr·mm², from 400 to 500 W/μsr·mm², from 10 to 500 W/μsr·mm², or any range formed by these values, or larger or smaller values.

In some cases, M² and BPP of the combined light beam 114a, along the slow-axis, can be smaller than 3 times, 2 times, 1.5 times, 1.2 times, 1.1 times, or 1.01 times the M² and BPP of the individual light beams used to generate the combined light beam 114a, along or in any range formed by any of these values or possibly larger or smaller.

For example, an individual light source (e.g., having a flared optical gain region) may generate a light beam having an M² along the fast-axis of the light source that can be substantially equal to 1, and an M² along the slow-axis of the light source that can be less than 2, and its BPP (along the also the slow-axis of the light source) can be from 0.3 to 0.6 mm-mrad for devices wherein the center wavelength of the light beam is at 980 nm and from 0.49 to 0.99 mm-mrad for devices wherein the center wavelength of the light beam is at 1550 nm.

In some cases, M² of the combined light beam along the fast-axis can be within 20%, 15%, 10%, 5%, 2% of 1 or substantially equal to or equal to 1 or any range formed by any of these values or possible larger.

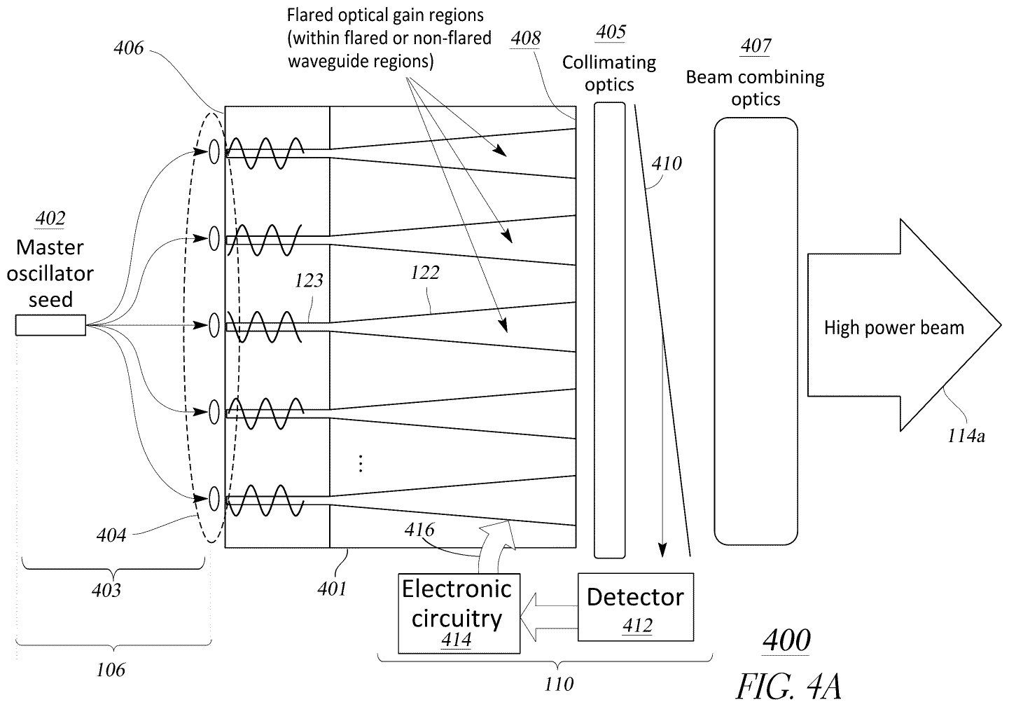

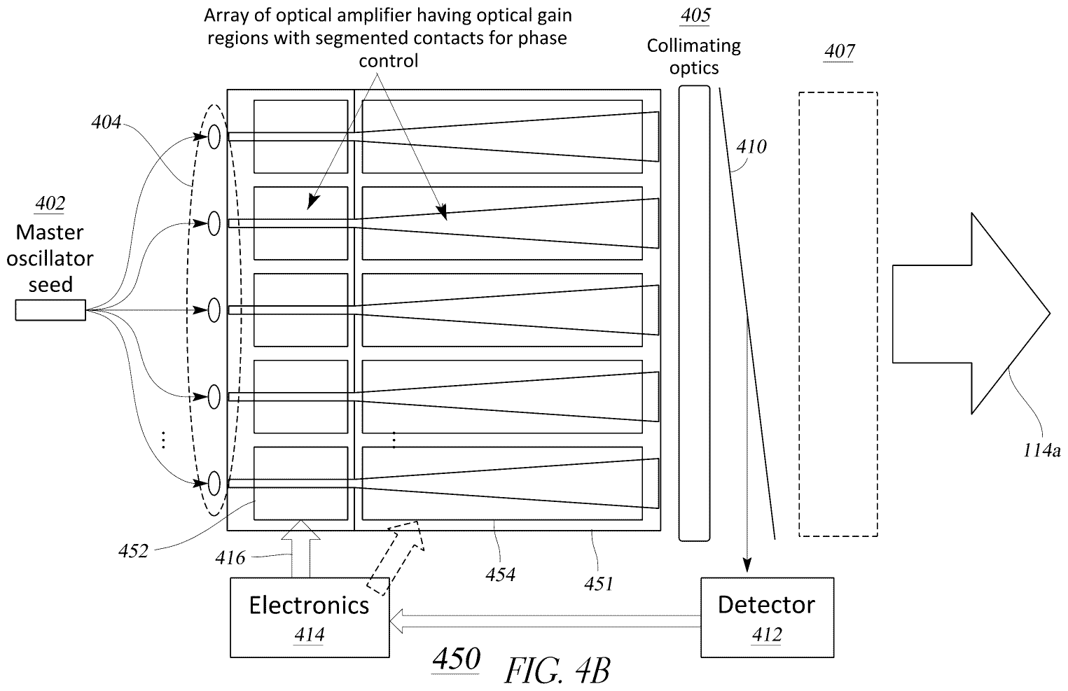

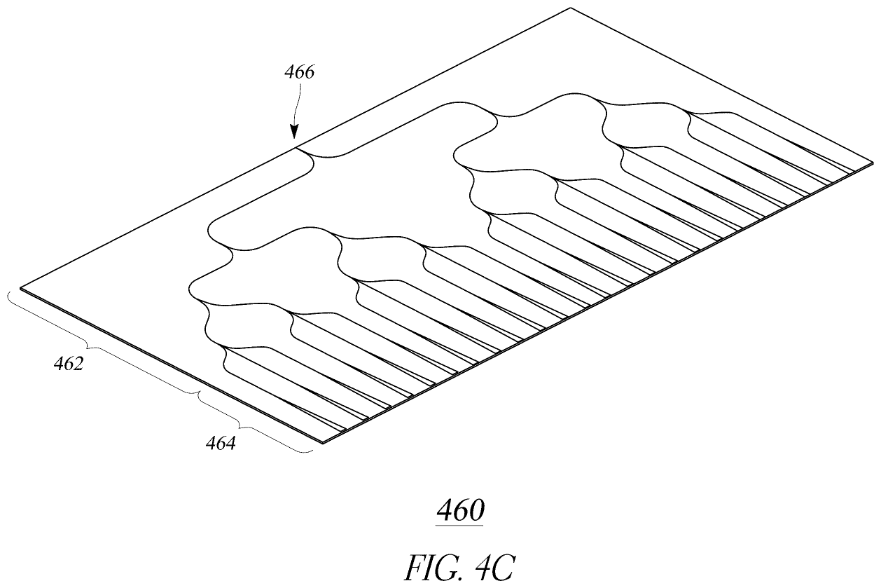

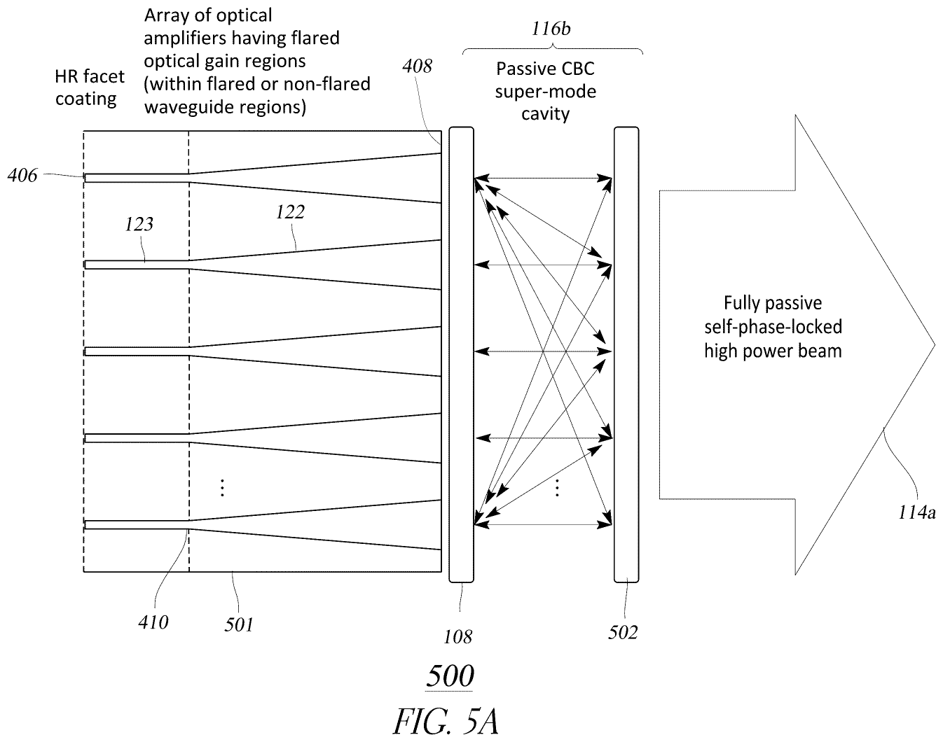

FIG. 4A is illustrates an example optical system 400 for generating a single wavelength combined light beam 114a using a seed laser 402 and an optical array 401 comprising N optical amplifiers having flared optical gain regions. In various implementations, N can be from 2 to 4, from 4 to 6, from 6 to 10, from 10 to 20, or any range formed by these values or possibly larger. The optical system 400 can be an optical system similar to the optical system 100 where the light source 104 comprises a single mode laser 402 that generates a light beam having a center wavelength λ_{seed}, the coupling section 106 comprising an optical power distributor 403 and a lens array 404, the optical array, the beam transforming section 108 comprising collimating optics 405, and the beam combining section 112 comprises beam combining optics 407. In some cases, the optical system 400 may use active CBC to generate a single wavelength high brightness light beam 114a.

An individual optical amplifier of the optical array 401 can be similar to the optical amplifier 120 having one or more corresponding features. For example, the individual optical amplifier may include a non-flared waveguide region optically connected to a flared waveguide region, where at least the flared waveguide region provides optical gain. In some cases, an individual optical amplifier of the optical array 401 may comprise a non-flared optical gain region and/or a flared optical gain region. In some such cases, the flared optical gain region can be a within a first waveguide region 122 (e.g., a flared or non-flared optical gain region) and the non-flared optical gain region can be within a second waveguide region 123 (e.g., a non-flared waveguide region).

The optical power distributor 403 can include a 1×N optical coupler that receives the light generated by the light source (e.g., laser) 104 and distributes it among N different optical channels. The 1×N optical coupler may be configured to provide an equal amount of power to each optical channel. In some examples, the optical coupler may comprise a network of waveguides with a single input waveguide coupled to N output waveguides, where input and output waveguides can be fiber optic waveguides or on-chip waveguides (e.g., waveguides monolithically fabricated on a semiconductor substrate).

The lens array 404 can include N lenses configured to couple light received from the N channels of the optical power distributor 403 to N optical amplifiers of the optical array 401. In some examples, an individual lens of the lens array 404 may receive a divergent light beam from an output waveguide of the optical power distributor 403 and generate a convergent light beam focused on an input of the non-flared waveguide region. In some examples, the input of the non-flared waveguide region and an output port of the flared waveguide region of an individual optical amplifier may comprise antireflection coating configured to reduce reflection at wavelengths emitted by the seed laser 402. In some such examples, the optical array 401 may comprise a photonic chip and input and/or output facets 406, 408 of the photonic chip may be anti-reflection (AR) coated to reduce reflection of light at wavelengths emitted by the seed laser 402.

The light beams received from the coupling section 106 are amplified by the individual optical amplifiers of the optical array 401 and output by the output ports of the flared waveguide sections. The collimating optics 405 collimates the light beams received from the optical array 401 and transmits the resulting collimated beams to the beam combining optics 407 that redirects and/or overlaps the individual light beams to generate the single wavelength combined light beam 114a having the same center wavelength as the source laser 402. In some examples, the M² and/or the BPP factor of the combined light beam 114a can be within 25%, 20%, 15%, 10%, 5%, 2%, 1% or substantially equal or equal to that of an individual light beam output by an individual optical amplifier of the optical array 401 or in any range formed by any of these values.

Given that the light beams are generated by a common source laser 402, the phases of the light beams output by different output ports may be locked to each other. In some cases, where the optical path from the source laser 402 to the corresponding output ports of different optical amplifiers are substantially equal, the optical phases of light beams output by different output ports can be substantially equal. In some other cases, the optical path from the source laser 402 to the corresponding output port of different optical amplifiers can be different causing the light beams output by different output ports to have different optical phases.

In some cases, the optical system 400 may include a feedback section 110 that controls the phase of the individual light beams output by the optical array 401, e.g., by controlling a current or voltage provided to at least a region of the respective optical amplifiers or phase control or phase shift sections (e.g., phase control or phase shift waveguide sections) delivering light to or receiving light from the respective optical amplifiers, possibly based on a measured optical power of at least some of the light beams. In some examples, the feedback section 110 may include a partial reflector 410 that redirects a portion light (e.g., the collimated light beams output by the collimating optics 405) toward a detector 412 that generates at least one detector signal. In some examples, the detector signal may be indicative of a total output power of light output by the optical array 401. Such a detector signal may be used to determine phase shift to be applied to one or more amplifier section.

An electronic circuitry 414, for example, may receive the detector signal and generate individual control signals 416, where an individual control signal is provided to a phase control region of an individual optical amplifier. In some cases, the phase control region may comprise an electrode extended over the non-flared waveguide region and flared waveguide region of the individual optical amplifier. In some examples, this electrode may be the same electrode used to pump the non-flared and flared waveguide regions.

In some cases, the detector 412 may comprise detector array where individual detectors of the detector array generate individual detector signals indicative of optical powers of the respective individual light beams (e.g., or collimated light beams), or a subset of individual light beams. In some such cases, the electronic circuitry 414 may generate the individual control signals based on the detector signals received from the respective detector element(s).

In some cases, the electronic circuitry 414 may dynamically adjust the individual control signals based on a measured total optical power or the individual measured optical powers to increase the measured total optical power, or individual measured optical powers. In some examples, the electronic circuitry 414 may comprise processing electronics or a processor and may comprise, for example, a non-transitory memory and a processor in communication with the non-transitory memory, where the processor is configured to execute machine readable instructions stored in the non-transitory memory, to generate the control signals based on one or detector signals received from the detector. In some cases, the processing electronics/processor and/or machine readable instructions may comprise an algorithm to determine and/or produce the control signals, for example, in some implementations, the processing electronics/processor may be configured to determine control signals that increase a measured optical power or a measured optical power distribution (e.g., measure by detector elements) after a measurement time step compared to a corresponding values measured in a previous measurement time step.

In some implementations, the phase control region of an individual optical amplifier, to which a control signal is provided, may comprise a first electrode (or electrode section) disposed on the non-flared waveguide region of the optical amplifier while a second electrode (or electrode section), which is electrically isolated from the first electrode, is used to pump the flared waveguide region of the individual optical amplifier. Advantageously, using electrically isolated electrode sections for optical phase and optical gain may allow independent control of optical gain provided by an amplifier section, and an optical phase of the amplified light beam output by the amplifier section. FIG. 4B illustrates an example optical system 450 for generating a single wavelength combined light beam 114a using a seed laser 402 and an optical array 451 having electrically isolated electrodes for phase and gain control. The optical system 450 may comprise one or more features described above with respect to the optical system 400. An individual, amplifier section of the optical array 451 may comprise a first electrode section 452 disposed, e.g., on a non-flared optical gain region (e.g., a non-flared optical waveguide region) of the amplifier section and a second electrode section 454 disposed on a flared optical region (e.g., a flared waveguide region) of the amplifier section. In some examples, the first electrode section 452 may be used to control the optical phase of light passing through the non-flared waveguide region based on a control signal 416 received from the electronic circuitry 414. The second electrode section 454 may control the optical gain provided to the light passing through the flared waveguide region. In some cases, the electronic circuitry 414 may provide a gain control signal to the second electrode section 454 based on a detector signal received from the detector 412. In some cases, a control signal may comprise a control current or voltage and a gain control signal may comprise a pump current (injection current). In some cases, the non-flared waveguide section may receive a pump current in addition to the control signal via the first electrode section 452 or another electrode (e.g., an electrode configured to affect the phase of light in the non-flared waveguide via thermo-optical or electro-optical effects).

In some cases, an independently controlled electronic source may provide a signal to the second electrode section 454 for optical gain control. Advantageously, when the phase of an individual light beam is controlled by applying a control signal to the first electrode section 452 and the intensity or power of the individual light beam is controlled by applying a control signal to the second electrode section 454, the optical system 450 can control the brightness of the resulting light beam 114a independent of its optical power.

In some cases, the phase of individual light beams output from the optical array 401 (or 451) may be controlled to generate a high brightness light beam propagating in a given direction. In some examples, the given direction may be a time dependent direction. The electronic circuitry 414 can be programed to control a direction of propagation of the combined light beam 114a by adjusting the control signals to the control regions of the individual optical amplifier sections. In some cases, the optical system 400 (or 450) may be used to generate and steer a high brightness light beam, e.g., within a predefined angle. In some such cases, the optical system 400 (or 450) may be used in a light detection and range finding (LIDAR) system to generate and steer a high brightness light beam directed to a target in an environment. In some cases, in addition to direction of propagation, the electronic circuitry may independently control power or intensity of the high brightness light beam 114a.

As described above, one or more sections or regions of the optical system 100 can be monolithically fabricated on a substrate. In some cases, monolithically fabricated sections may be integrated on single chip. In some implementations, the optical coupling section 106 and the optical array 102 of the optical system 100 may be monolithically integrated on a single photonic chip. FIG. 4C illustrates an example photonic chip 460 that includes an optical distribution region 462 and an optical amplification region 464. The optical distribution region 462 comprises an input port 466 or input facet through which light from the light source 104 (e.g., a seed laser) is received. The optical distribution region 462 distributes the light received from the input port 466 among a plurality of the optical amplifier elements (or sections) of the optical amplification region 464. In the example shown, the optical distribution region 462 includes a waveguide network comprising a plurality of interconnected 1×2 and 1×3 optical beamsplitters, multi-mode interference couplers, or directional couplers forming a 1×24 optical power distributor configured to distribute optical power received via an optical source via the input port 466 among 24 optical amplifiers having tapered optical gain regions. In some cases, the optical distribution region 462 and an optical amplification region 464 can be formed in a common layer of a substrate. In some cases, the optical distribution region 462 and an optical amplification region 464 can be formed in two different layers or regions of a substrate comprising different materials. In some cases, the optical distribution region 462 and an optical amplification region 464 can be formed on two separate chips of substrates. In these cases, output ports of the optical distribution region 462 may be optically coupled to the input ports of the optical amplifier elements in the optical amplification region 464. The optical coupling between the optical distribution region 462 and the optical amplification region 464 may comprise butt-coupling, coupling with lenses, or photonic wire bonding.

In some implementations, the optical system 400 (or optical system 450) may comprise the photonic chip 460 where the optical distribution region 462 serves as the optical power distributor 403 and the optical amplification region 464 serves as the optical array 401 (or optical array 451). In these implementations the optical power distributor 403 is directly coupled to the optical array 401 (or optical array 451) without using a lens array.

In some cases, the seed laser may be fabricated on a separate chip and optically coupled to the optical distribution region 462 (via butt-coupling, lens coupling, or photonic wire bonding). Alternatively, the seed laser may be monolithically fabricated with the optical distribution region 462, or the optical distribution region 462 and the amplification region 464, on a common chip.

In some cases, the plurality of optical path lengths from the input port 466 to individual optical amplifier sections may be substantially equal. Alternatively, or in addition the individual optical path lengths from the input port 466 to the individual optical amplifier sections may be actively controlled (via phase control section) to reduce the differences between the optical path lengths from the input port 466 to different optical amplifier sections.

In some cases, in addition or in alternative to the optical splitters/couplers and/or optical amplifiers, the optical distribution region 462 and/or the optical amplification region 464, may include electro-optical elements (e.g., for phase control), polarization control elements, optical delays, and the like. In some cases, these additional elements can be integrated (e.g., monolithically) with the optical splitters/couplers on the same chip.

As described above with respect to FIG. 1B, in some cases an optical system may generate a high brightness beam using passive coherent beam combination, e.g., by coupling the optical phases of different light beams generated and sustained in a plurality of external cavity lasers.

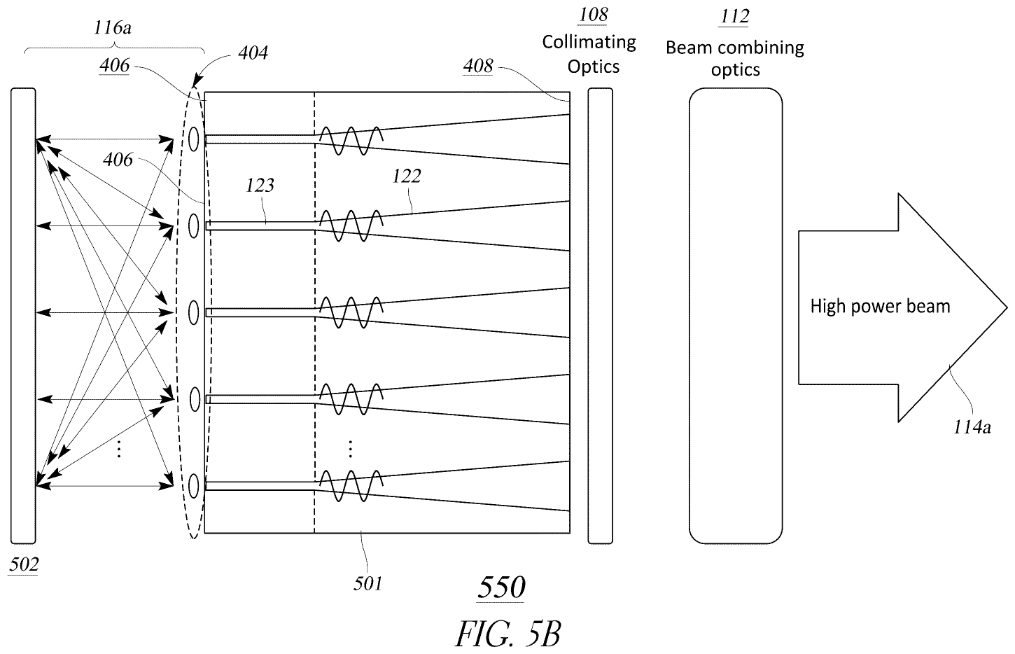

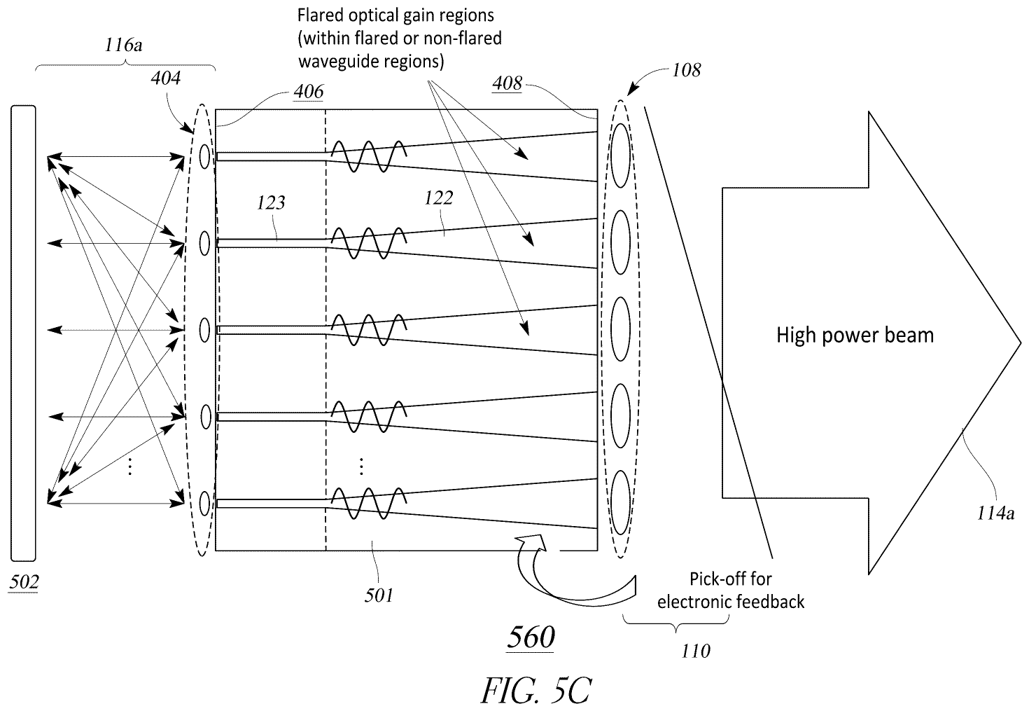

FIG. 5A illustrates an example optical system 500 for generating a combined light beam 114a by forming a super-mode cavity in the output side of an optical array 501 comprising optical gain sections having a flared optical gain region. In some cases, an optical gain section of the optical array 501 may be similar to the optical amplifier 120 with an additional optical reflector disposed at a position along the optical amplifier 120 between the input port of the second waveguide region 123 and the output port of the first waveguide region 122. In some examples, the optical reflector may be disposed at the interface between the first and the second waveguide regions 122/123 (e.g., the non-flared and the flared waveguide regions). In some examples, the optical reflector may be disposed at the input port of the second waveguide region 123. In some cases, the optical reflector at the input port of the second waveguide region 123 may comprise a region of highly reflective (HR) coating disposed on an input facet 406 of the optical array 501.

In some cases, a plurality of external cavity lasers may be formed by the individual reflectors, the corresponding individual optical gain regions, and a front cavity coupler region 116b configured to receive individual light beams output by respective optical amplifier sections. The front cavity coupler region 116b allows the individual external cavity lasers to interact in a super-mode configuration. In some cases, the front cavity coupler region 116b may comprise a beam transforming section 108 disposed at the output side of the optical array 501 (where the individual light beams are output), and a distributed reflection device (DRD) 502 placed a distance from the beam transforming section 108.

The distributed reflection device (DRD) 502 may include one or more reflectors and lenses configured to cross-couple light between different optical amplifiers in the optical array 501 such that emission from an individual external cavity laser contributes to feedback into other external cavity lasers resulting, in some implementations, in simultaneous operation of all elements in a single, coherent mode (herein referred to as super-mode). The cross-coupling between the external laser cavities can passively phase lock the laser beams generated by the plurality of the external cavity lasers. The DRD 502 can also be configured to transmit a portion of an individual laser beams. The transmitted portions of the phase-locked laser beams may be combined to generate the high brightness light beam 114a. The front cavity coupler region 116b and the optical array 501 may be configured such that an individual external cavity sustains light having wavelengths within a frequency bandwidth centered at a common cavity wavelength for at least a portion of the plurality of external cavities. As such, in some implementations, the combined light beam 114a can have a center wavelength substantially equal to the common cavity wavelength.

In some cases, the front cavity coupler region 116b can be configured to preserve the quality of the light beams coupled out of the individual laser elements while coupling them between different elements to provide optical feedback. In some examples, the front cavity coupler region 116b, may be configured to prevent filamentation in the flared optical gain regions the optical array 501. In some examples, the front cavity coupler region 116b may be configured to transform a light beam coupled out of an individual laser element into a plurality of individual transformed lights beams and redirect them to other individual elements of the optical array. In some cases, an individual transformed light beam may have a beam profile substantially identical to that of the fundamental mode of the non-flared or flared waveguide region of an element of the optical array. In some cases, a cavity coupler region may comprise a 4-f optical system such that the beam entering an individual element (e.g., via a front facet or a back facet) as feedback, is an image (e.g., with a magnification of 1) of the light beam that exits the individual element (to provide feedback to other elements).

In some implementations, the external cavities formed by the cavity coupler region may improve the quality of light beam generated by the individual external cavity lasers. By providing feedback to this fundamental mode, the lasing threshold may be reduced, and the laser may preferentially operate in this fundamental mode. A tapered diode laser in such a cavity may have a better beam quality compared to the same tapered diode laser without the external cavity.

In some cases, the optical system 500 may comprise a Talbot cavity or a Fourier injected resonator cavity (also known as “FIRE” cavity). In some examples, the DRD 502 may include a one or more reflective surfaces and one or more lenses between the reflective surface and the optical array 102. In some examples, the beam transforming device and the DRD 502 of the optical system 500, or the DRD 502 and the lens array 404 of the optical system 550 may form a 4F optical imaging system that image a light beam received from an optical amplifier element or section to one or more other optical amplifier elements of the array 501 or 551 (e.g., with a magnification of 1).

Examples of phase locked laser arrays having super-mode cavities are discussed in U.S. Patent number US 2004/0170204 A1 issued on Sep. 2, 2004, and U.S. Pat. No. 7,539,232 B1 issued on May 26, 2009, which are hereby incorporated by reference herein in its entirety.

The optical gain section of the optical array 501 may be pumped using individual electrodes to generate and sustain a plurality of laser beams in the super-mode cavity. In some cases, an individual electrode may comprise a first section disposed on a non-flared waveguide region and a second section disposed on a waveguide region (flared or non-flared) having a flared optical gain region, where the first and the second electrode sections are electrically isolated. Similar to the optical systems 400 and 450, the individual electrodes or electrode sections may be used to provide injection currents and, in some cases, control signals to the electrodes or electrode sections, for example, to control the phase of light propagating in the corresponding waveguide region. In some cases, the second electrode section can be a tailored electrode section configured to generate a flared optical gain region within a flared or non-flared waveguide region.

FIG. 5B illustrates another example optical system 550 for generating a high brightness light beam by forming a super-mode cavity in the back side of an optical array 501 comprising optical gain sections having a flared optical gain region. The optical system 550 may comprise one or more features described above with respect to the optical system 500. For example, the optical array 501 of the optical system 550 can be substantially identical to the optical array 501 of the optical system 500. However, in this case, a back cavity coupler region 116a is placed at the back side of the optical array 501 and a lens array 404 is used to couple light received from the DRD 502 to the individual non-flared waveguide sections of the optical array 501.

In some cases, passive CBC based on the super-mode cavity may include active phase control or optical gain control. In these cases, the super-mode cavity configuration locks the phases of the individual external cavity lasers and active phase control may be used to compensate for optical path length differences between individual output light beams sustained and generated by different laser elements, e.g., due to fabrication imperfections. FIG. 5C illustrates an example optical system 560 for generating a combined light beam 114a by forming a super-mode cavity in the back side of an optical array 501 comprising phase controlled optical gain sections having flared optical gain regions. The optical system 560 may comprise one or more features described above with respect to the optical system 500. For example, the optical system 560 may comprise a feedback section 110 configured to receive light output by the optical array 102 and provide control signals to the individual external cavity lasers (to one or both passive or active section or the individual waveguide regions) to control the optical power and/or the optical phase of light beams generated by the individual external cavity lasers. In some cases, the beam transforming section (e.g., collimating optics) 108 may be placed between the optical array 501 and the feedback section 110 and may comprise and array of lenses configured to collimate the individual light beams output by the optical array 501. The current and phase control of the individual external laser cavity elements of the optical system 560 may comprise one or more features described above with respect to the optical system 400 or the optical system 450.

In some cases, e.g., where the optical array 501, 551, or 560 comprises a photonic chip, a front facet 408 of the optical array 501 or a back facet 406 of the optical array 551 or 560 may be anti-reflection (AR) coated to reduce reflection of light at wavelengths within a cavity bandwidth of the corresponding external cavities.

In various implementations, the combined light beam 114a generated by the optical systems 500, 550, and 560 can be a light beam having a wavelength within a bandwidth centered at a center wavelength where the bandwidth can be from 10-9 to 0.001 nm, from 0.001 nm to 0.1 nm, from 0.1 to 1 nm, from 1 to 10 nm, from 10 to 100 nm, or any ranges formed by these values or possibly larger or smaller.

As mentioned above, an optical system may include a plurality of passively phase locked light sources comprising evanescently coupled waveguides. In some cases, the plurality of source lasers may comprise flared optical gain regions. In some cases, the plurality of phase locked light beams generated by evanescently coupled lasers, may be amplified by a plurality of flared optical gain regions prior to being coherently combined.

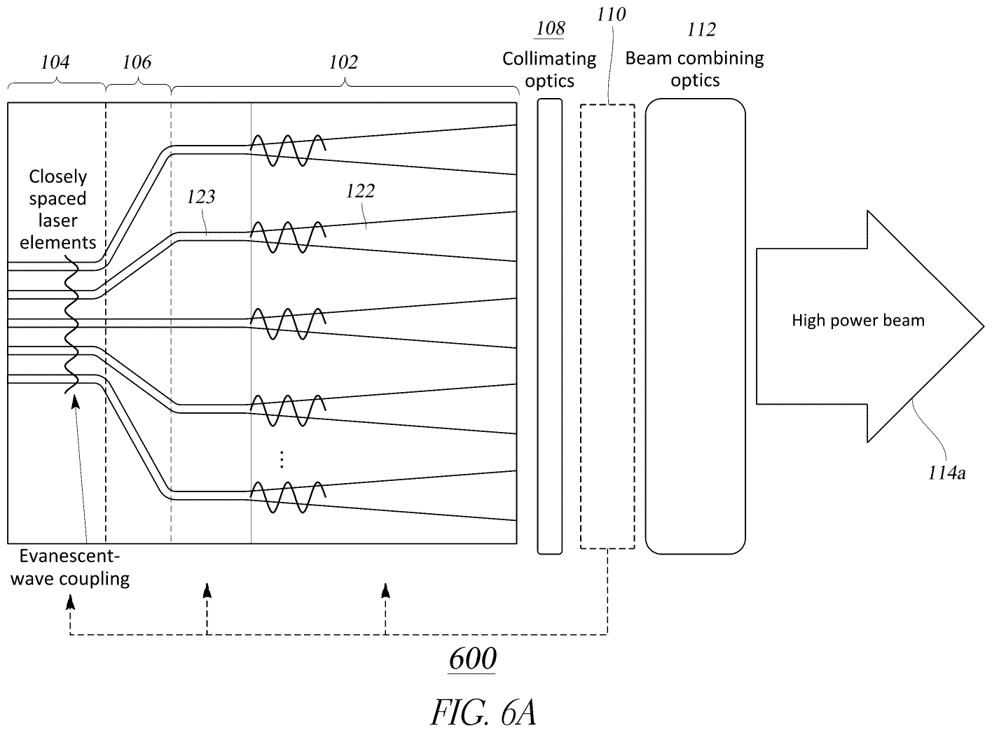

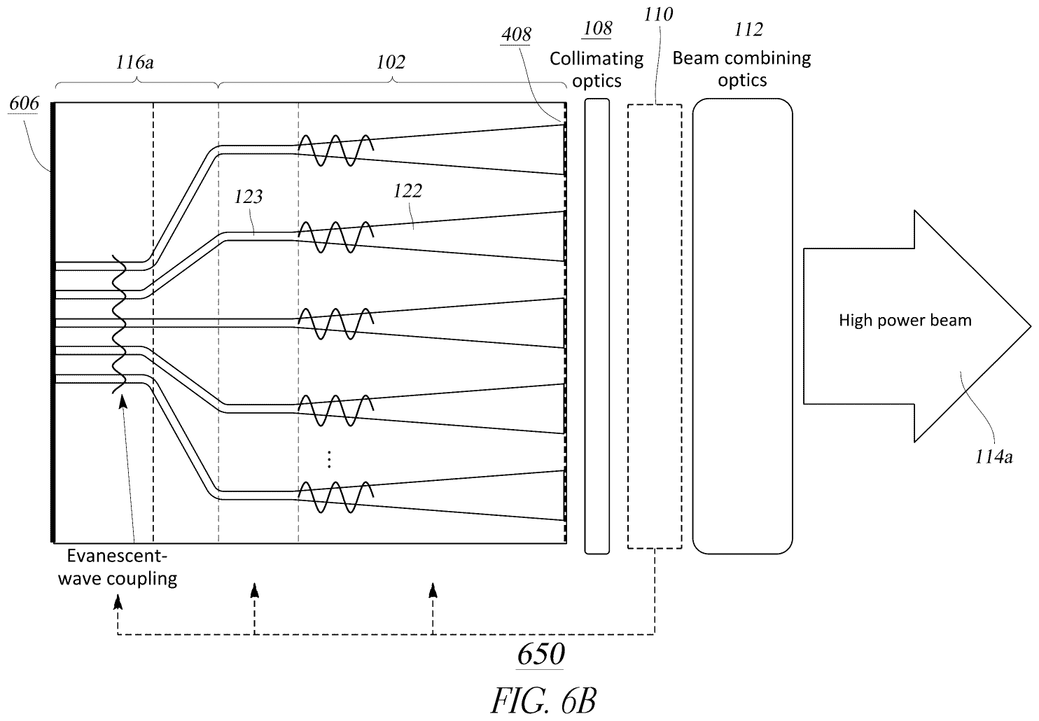

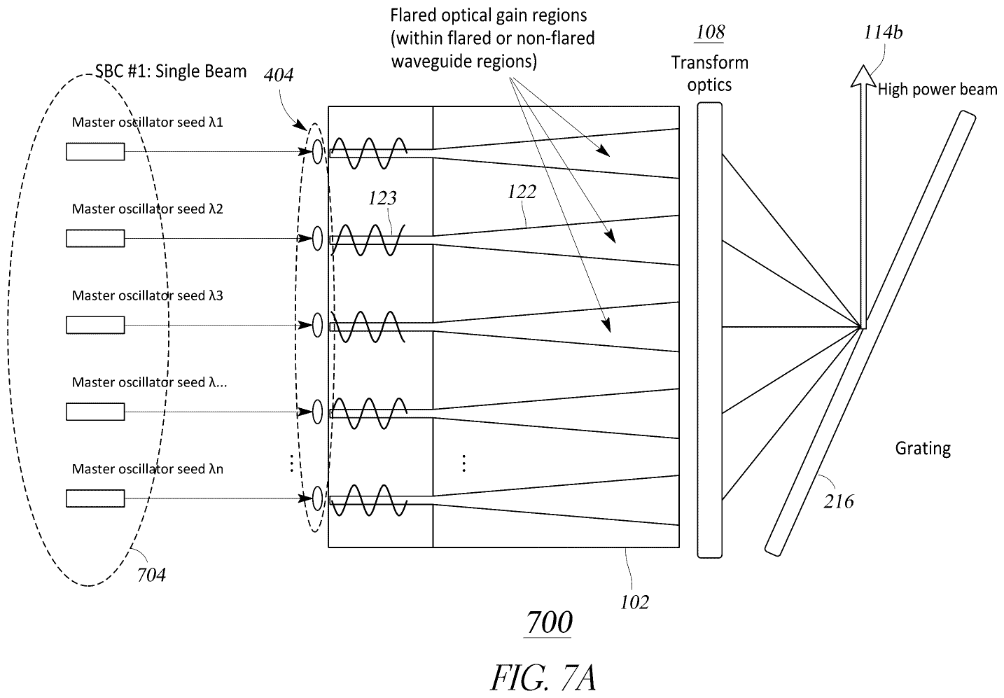

FIG. 6A illustrates an example optical system 600 for generating a combined light beam 114a using a light source 104 comprising an array of evanescently coupled seed lasers. The seed lasers may have substantially the same wavelengths (center wavelengths) and may be pumped via individually controlled electrodes or a single electrode. An individual seed laser may comprise an active waveguide that provides optical gain within a cavity formed between a back reflector and a front reflector. In some cases, an individual back reflector may comprise a region of a common highly reflective facet of the light source 104. In some cases, the front reflector may comprise a DBR or SGDBR reflector. In various implementations, the individual seed lasers may be wavelength tunable (e.g., by thermal or electro-optical tuning of a reflector). The optical system 600 further includes an optical coupling section 106 that couples light from individual seed lasers to the individual amplifier sections of the optical array 102. In some examples, the optical coupling section 106 may comprise a plurality of monolithically fabricated waveguides. The light generated by an individual seed laser may be provided to an optical gain section of the optical array 102 for further amplification. Since the seed laser sources are evanescently coupled, the light beams generated by these laser sources are phase-locked and after optical amplification the resulting light beams can be combined to generate the high brightness beam 114a. The optical system 600 may include a beam transforming section 108 (e.g., collimating optics) and a beam combining section 112 configured to combine the amplified light beams received from the optical array 102 to generate the high brightness light beam 114a. In some implementations, the optical system 600 may include a feedback section 110 that provides control or pump signals to the individual optical amplifier sections of the optical array 102 and/or to the individual seed lasers of the light source 104. In some implementations, the light source 104, the optical coupling section 106, and the optical array 102 may be integrated on a single carrier chip or monolithically fabricated on a single substrate. In some examples, where two or more of the light source 104, the optical coupling section 106, and the optical array 102 are fabricated on separate chips, butt coupling, lens coupling, or photonic wire bonding may be used to optically couple the corresponding individual elements of the chips.

FIG. 6B illustrates an example optical system 650 for generating a combined light beam 114a using a plurality of light sources comprising an array of evanescently coupled waveguides. In some implementations, the optical system 650 may comprise an optical array 102 comprising a plurality of optical amplifier sections having flared optical gain regions, and a back cavity coupler region 116a comprising an array of evanescently coupled waveguides. In some cases, an individual waveguide of the back cavity coupler region 116a may comprise a back reflector that forms a laser cavity with a front reflector disposed at an input port of an individual optical amplifier section (e.g., input of a non-flared waveguide region or non-flared optical gain region), at an interface between the non-flared and flared optical gain regions (e.g., between the non-flared and flared waveguide regions), at an output port of the individual optical amplifier section, or another position along the individual optical amplifier section. In some cases, an individual back or front reflector may comprise a region of a highly reflective facet. In some cases, an individual back or front reflector may comprise a DBR, an SG-DBR, or other optical reflectors comprising a change (e.g., a periodic change) of the effective refractive index of a portion of a waveguide (e.g., generated by changing the refractive index or tailoring the waveguide structure). Since an individual laser cavity includes a waveguide section evanescently coupled to waveguide sections of adjacent laser cavities, the light beams generated by the individual laser sources formed by the optical array 102 and the back cavity coupler region 116a can be phase-locked. As such, in the optical system 650, the plurality of light beams generated by the plurality of lasers can be coherently combined to generate the combined light beam 114a. In some cases, the phases of the individual optical gain sections in the optical array 102 may be further controlled by a feedback section 110 to reduce a phase difference that may occur between the individual phase-locked light beams in the optical array 102 section. In some implementations, the back cavity coupler region 116a, and the optical array 102 may be integrated on a single carrier chip or monolithically fabricated on a single substrate. In some examples, where the back cavity coupler region 116a and the optical array 102 are fabricated on separate chips, butt coupling or photonic wire bonding may be used to optically couple the corresponding individual elements of the chips. In some cases, a back facet 606 and a front facet 408 of a photonic chip comprising the back cavity coupler region 116a and the optical array 102 may be coated with a high reflectivity layer, a partially reflective layer, or an anti-reflective layer.

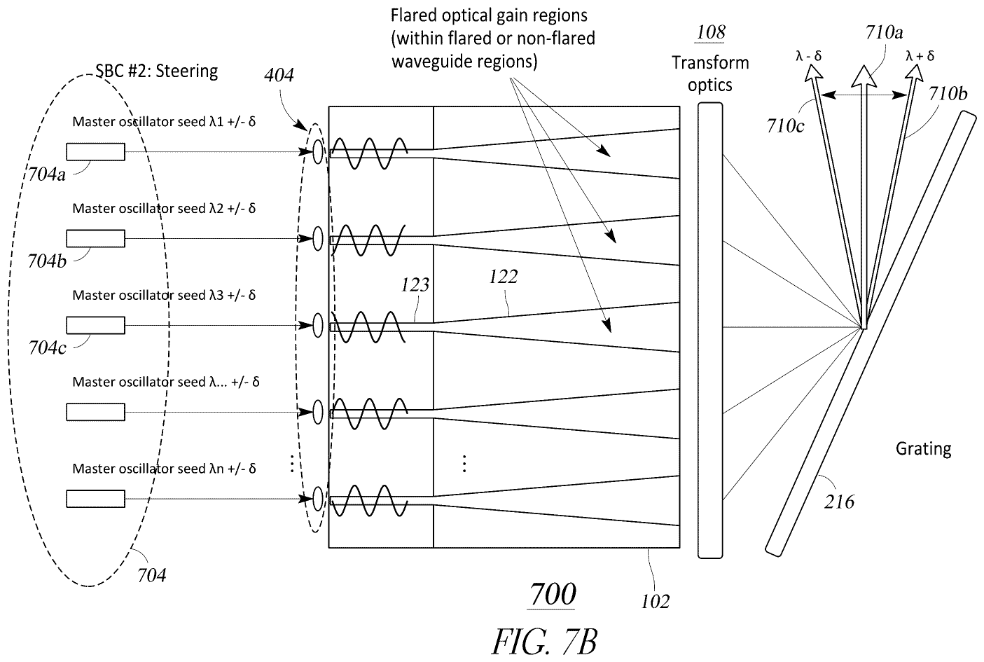

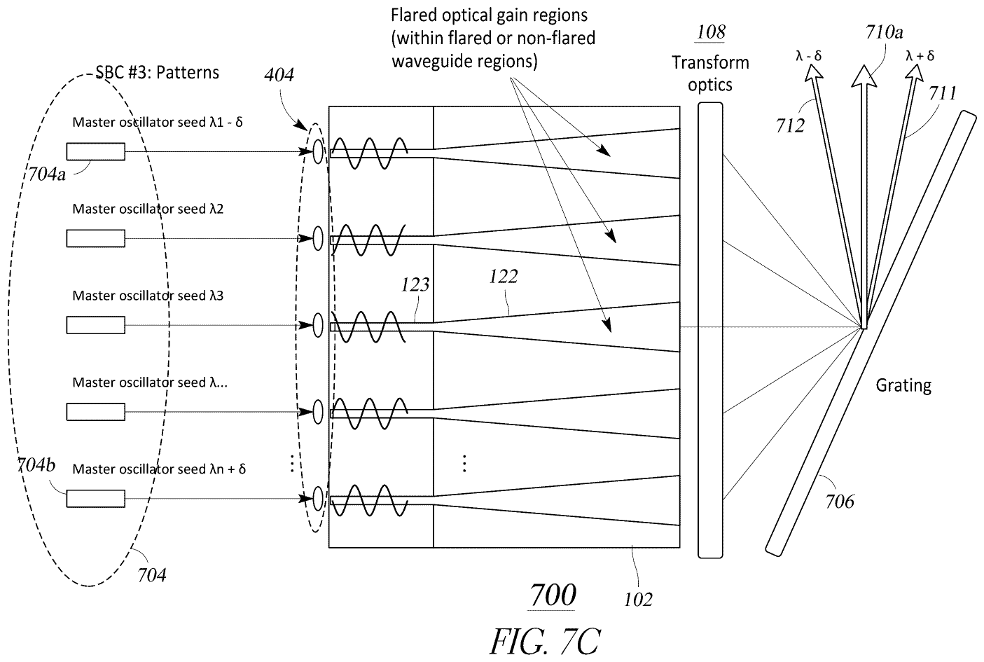

FIG. 7A illustrates an example optical system 700 for generating a multi-wavelength high brightness light beam based on SBC and using seed lasers having different wavelengths and optical amplifiers having flared optical gain regions. In some implementations, the optical system 700 may include an array of seed lasers 704, a lens array 404, an optical array 102, a beam transforming section 108 and an optical grating 216. The array of seed lasers 704 may comprise a plurality of seed lasers configured to generate a plurality of light beams having different wavelengths. The plurality of light beams can be coupled to the plurality of optical amplifier elements of the optical array 102 and the resulting amplified light beams are transformed and/or redirected by the beam transforming section 108 to a region of the grating 216. In some cases, the beam transforming section 108 may be configured to transform and/or redirect the amplified light beams such that when they are diffracted by the grating 216 they form a multi-wavelength high combined light beam 114b. In some cases, the radiance or brightness of the high brightness combined light beam 114b can be larger than the radiance or brightness of an individual amplified light beam by a factor of N or within 20%, 10%, 5%, 2%, 1% thereof or any range formed by any of these values, where N is the number of amplified light beams output from the optical array 102. In some cases, the beam transforming section 108 may comprise collimating optics, lenses, prisms, or other optical elements configured to redirect the plurality of light beams received from the optical array 102 to the optical grating 216.

In some cases, an individual optical amplifier element comprises at least a flared optical gain region. In some cases, the individual optical amplifier element may comprise the optical amplifier 120 or 126 described above with respect to FIG. 1C. In some implementations, the optical amplifier elements may have substantially identical optical gain spectra and an optical gain bandwidth of an individual optical amplifier element can be larger than a wavelength difference between seed laser elements having the smallest and largest wavelengths of the seed lasers (e.g., the seed laser array) 704. In some cases, seed lasers 704 may generate a plurality of light beams having equally spaced wavelengths.

In some implementations, the seed lasers (seed laser array) 704 may comprise a plurality of wavelength tunable lasers. In some examples, wavelengths of the individual seed lasers may be adjusted to generate a high combined light beam 114b having a predefined spectral power distribution. In some examples, the wavelengths of the individual seed lasers may be adjusted to generate a high brightness combined light beam 114b that propagates in a predefined direction. In some such examples, the wavelengths of the individual seed lasers may be dynamically controlled to change the propagation direction of the high brightness combined light beam 114b. FIG. 7B illustrates an example where the optical system 700 is used for generating and steering (or scanning) a multi-wavelength high brightness light beam. Detuning the wavelengths of the seed lasers from a series of initial wavelength values, λ₁, λ₂, λ₃, . . . λₙ, (where n is a numbed of seed lasers), which generate a high brightness beam 710a, may rotate the light beam by an angle determined by the wavelength detunings. For example, changing 80 ₁, λ₂, λ₃, . . . λₙ, to λ₁±δ, λ₂±δ, λ₃δ, . . . λₙ±δ, may generate the high brightness beams 710b or 710c that are rotated with respect to the high brightness beam 710a by an angle ±θ where θ is determined by δ. Using this approach, the optical system 700 may be used for generating and steering a high brightness beam for variety of applications, including but not being limited to LIDAR systems.

In some examples, θ can be from 0.1 degrees to 1 degrees, from 1 degree to 5 degrees, from 5 degrees to 10 degrees, from 10 degrees to 20 degrees, from 20 degrees to 30 degrees, from 30 degrees to 40 degrees, or any range formed by these vales or larger or smaller values.

FIG. 7C illustrates an example where the optical system 700 is used to generate a multi-wavelength high brightness optical pattern. In some examples, detuning one or more wavelengths of the seed lasers from a series of initial wavelength values, λ₁, λ₂, λ₃, . . . λₙ, (where n is a numbed of seed lasers), which generate a single high brightness beam 710a, may generate additional light beams propagating along directions different from the direction of propagation of the initial high brightness light beam 710a. For example, changing the wavelengths of the first and last lasers 704a, 704b of the seed laser array 704 to 21-8 and λₙ+δ may generate two additional light beams 711 and 712 that are rotated with respect to the high brightness beam 710a by an angle θ where θ is determined by 8. Using this approach, the optical system 700 may be adjusted to generate a plurality of additional beams forming a predefined pattern.

In some cases, the grating 706 in the optical system 700 described above, may be replaced by a dispersive optical element (e.g., a prism) that can redirect light beams incident on the optical element at different angles along a single direction.

In some cases, the optical system 700, may dynamically adjust the optical phases of at least a portion of the light sources or laser in the optical system 210 or 700 to continuously scan the high brightness light beam within an angular range (e.g., a predefined angular range).

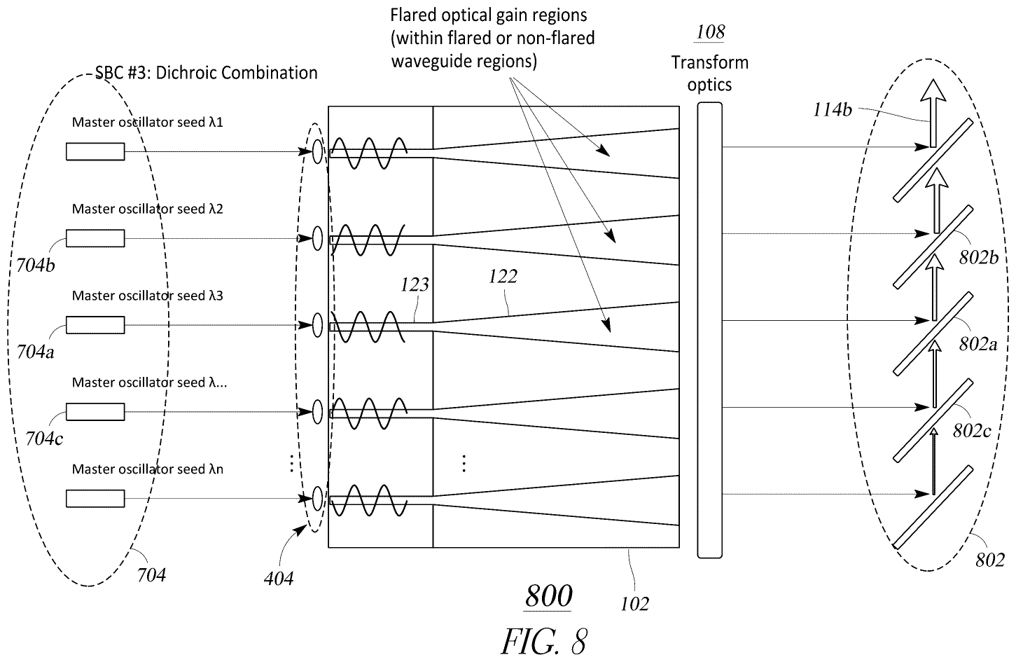

FIG. 8 illustrates another example optical system 800 for generating a multi-wavelength high brightness light beam using an array of seed lasers having different wavelengths. The optical system 800 may comprise one or more features described above with respect to the optical system 700. Similar to the optical system 700, the optical system 800 comprises an array of seed lasers 704 optically coupled to an optical array 102. The seed laser array generates light beams with different wavelengths that are amplified by the optical amplifier segments of the optical array 102. The beam transforming section 108 of the optical system 800 comprises collimator optics configured to collimate amplified light beams received from the 102. An array of dichroic beams splitters 802 receive the amplified light beams and combine them to generate a multi-wavelength high combined light beam 114b. An individual dichroic splitter in the dichroic beamsplitter array may be configured to receive and to reflect a light beam from an optical amplifier element of the optical array 102 while transmitting light beams received from the other dichroic beams splitters. For example, the dichroic beam-splitters 802a, 802b, 802c may receive and reflect light beams having wavelengths λa, Ab, Ac, respectively, generated by respective seed lasers 704a, 704b, 704c and amplified by three individual optical amplifier sections of the optical array 102. The light beam reflected by the dichroic beamsplitter 802c may be transmitted through the dichroic beamsplitters 802a, 802b, and the light beam reflected by the dichroic beamsplitter 802a may be transmitted through the dichroic beamsplitter 802b. As a result, light beams received by the dichroic beamsplitters 802a, 802b, 802c may be combined as a single high brightness light beam that is transmitted to a fourth dichroic beamsplitter. Using this configuration, light beams having different wavelength are sequentially combined to generate a high brightness multi-wavelength light beam 114b. In some examples, a dichroic beamsplitter may comprise a multilayer dielectric coating to provide high reflectance within a narrow bandwidth around a wavelength of light emitted by an individual seed laser, and high transmission for other wavelengths emitted by the seed laser array 704.

In various implementations, a reflector disposed in a location along any of the optical amplifier, lasers, or MOPAs discussed above or anywhere therebetween may comprise a comb mirror having a comb-like reflection spectrum.

In various implementations, a reflector disposed in a location along any of the optical amplifiers, lasers, or MOPAs discussed above or anywhere therebetween may comprise a narrowband reflector.

In various implementations, a phase control region or a reflector disposed in a location along any of the optical amplifier, lasers, or MOPAs discussed above or anywhere therebetween may be thermo-optically or electro-optically tuned. In some cases, phase control region or a tunable reflector may comprise an electrode through which a current or voltage is provided to an electro-optically active region phase control region or the reflector, or a heating element (e.g., a resistive heater) that is in thermal communication with the reflector or phase control region.

In various implementations, a power of an individual light beam of the plurality of light beams generated or amplified by the optical array 102, 200, 210, 401, 451, 501, can be from 0.1 Watts to 0.5 Watts, from 0.5 Watts to 1 Watt, from 1 Watt to 5 Watts, from 5 Watts to 10 Watts, from 10 to 100 Watts, from 100 to 1000 Watts, or any range formed by any of these values or possibly larger or smaller.

A beam propagation parameter of the combined light beam output by the optical array 102, 200, 210, 401, 451, or 501, can be smaller than 3 times, 2 times, 1.5 times, 1.2 times, 1.1 times, or 1.01 times of a beam propagation parameter of a light beam of the plurality of light beams or any in an range formed by any of these values or possibly larger or smaller.

In various implementations, a number of optical gain sections, lasers, or optical amplifiers in the optical array 102, 200, 210, 401, 451, or 501 can be from 2 to 10, from 10 to 100, from 100 to 1000, or any ranges formed by these values or possibly larger or smaller.

In some examples, a phase difference between two individual light beams of the optical systems 100, 101, 200, 400, 450, 500, 550, 560, before being combined into the combined beam 114 or 114a, can be less than 0.001 degree, 0.1 degree, 1 degree, less than 5 degrees, or less than 10 degrees or any range formed by any of these values or possibly larger or smaller.

In various embodiments described above with respect to optical systems 100, 101, 200, 400, 450, 500, 550, 560, 650, 700, or 800, a flared waveguide region may be replaced by a non-flared waveguide region with a flared optical gain region or a flared pumped region.

### EXAMPLE EMBODIMENTS

Various additional example embodiments of the disclosure can be described by the following clauses:

### Example Group I

Example 1. An optical system for generating a combined light beam by combining a plurality of light beams, the optical system comprising:
a source laser;
an optical array chip comprising a plurality of optical amplifiers configured to receive light from the source laser and output the plurality of light beams, wherein an individual optical amplifier of the plurality of optical amplifiers comprises:
   a first waveguide section extending from a first end to a second end in a longitudinal direction and a second waveguide section extending from the second end to a third end in the longitudinal direction, wherein the second waveguide section comprises a flared optical gain section that has an output lateral width at the third end larger than an input lateral width at the second end, and supports propagation of at least two lateral modes,
   a first electrode disposed on the first waveguide section, and
   a second electrode disposed on the second waveguide section, wherein the second electrode is electrically isolated from the first electrode;
an electronic system configured to adjust a voltage or current provided to the first electrode to increase a brightness of the combined light beam.

Example 2. The optical system of Example 1, further comprising a photodetector configured to receive at least a portion of an individual light beam of the plurality of light beams and generate at least one detector signal indicative of optical power or radiance of the individual light beam or the combined light beam, wherein the electronic system adjusts the voltage or the current provided to the first electrode based at least in part on the at least one detector signal.

Example 3. The optical system of Example 2, wherein the photodetector comprises a plurality of detector elements configured generate at least two detector signals indicative of optical power or optical intensity combined light beam at two different spatial locations, wherein the electronic system adjusts the voltage or the current provided to the first electrode based at least in part on the at least two detector signals.

Example 4. The optical system of Example 1, wherein the electronic system adjusts a voltage or current provided to the first electrode to decrease a difference between an optical phase of a first light beam output by a first optical amplifier of the plurality of optical amplifiers and a second light beam output by a second different optical amplifier of the optical array chip.

Example 5. The optical system of Example 1, wherein the second waveguide section comprises a flared optical waveguide having a lateral width that increases along the longitudinal direction.

Example 6. The optical system of Example 1, wherein the first waveguide section comprises a non-flared optical waveguide.

Example 7. The optical system of Example 1, wherein the second electrode is a patterned flared electrode configured to generate an injection current distribution across the second waveguide section to selectively amplify a fundamental lateral mode of the second waveguide section.

Example 8. The optical system of Example 7, wherein the second electrode extends in the longitudinal direction from a narrow end to a wide end, and a lateral width of the second electrode increases and decreases multiple times with position along the longitudinal direction, and wherein the narrow end is closer to the second end of the second waveguide section and has lateral width smaller than that of the wide end.

Example 9. The optical system of Example 8, wherein the lateral width of the second electrode varies periodically in the longitudinal direction with a width variation period.

Example 10. The optical system of Example 9, wherein the second electrode comprises a single conductive layer.

Example 11. The optical system of Example 1, wherein the first electrode controls a phase of light transmitted via the first waveguide section.

Example 12. The optical system of Example 1, wherein the first electrode controls a phase of light transmitted through the first waveguide section via a thermo-optical effect or an electro-optical.

Example 13. The optical system of Example 1, further comprising an optical distributor configured to receive light from the source laser and couple the received light to the plurality of optical amplifiers.

Example 14. The optical system of Example 13, wherein the optical distributor comprises a network of waveguides monolithically fabricated on a substrate.

Example 15. The optical system of Example 13, wherein the optical array chip comprises a substrate on which the plurality of optical amplifiers are monolithically fabricated.

Example 16. The optical system of Example 15, wherein the optical distributor and optical array chip are monolithically fabricated on a common substrate.

Example 17. The optical system of Example 14 wherein the network of waveguides comprises a plurality of optical power dividers.

Example 18. The optical system of Example 1, further comprising a collimator configured to collimate the light received from the plurality of optical amplifiers.

Example 19. The optical system of Example 1, further comprising a beam combiner configured to combine the plurality of light beams from the plurality of optical amplifiers.

Example 20. The optical system of Example 1, wherein the plurality of light beams output from the plurality of optical amplifiers are phase-locked.

Example 21. The optical system of Example 20, wherein the combined light beam comprises a coherent combination of the plurality of light beams.

Example 22. The optical system of Example 1, wherein optical power of one of light beam of the plurality of light beams is from 0.1 Watts to 100 Watts.

Example 23. The optical system of Example 1, wherein a beam propagation parameter of the combined light beam is smaller than 1.2 times a beam propagation parameter a light beam of the plurality of light beams.

Example 24. The optical system of Example 23, wherein beam propagation factor (M²) of the combined light beam is less than 1.5.

Example 25. The optical system of Example 1, wherein the plurality of optical amplifiers comprises N optical amplifiers and a radiance of the combined light beam is greater than a radiance of a light beam of the plurality of light beams by at least a factor of N.

### Example Group II

Example 1. An optical system for generating a combined light beam using a plurality of laser beams having different wavelengths, the plurality of laser beams generated by a plurality of light sources, the optical system comprising:
an optical array chip comprising a plurality of optical gain elements, wherein an individual optical gain element comprises:
   a waveguide region extending from a back end to a front end of the individual optical gain element along a longitudinal direction, the waveguide region comprising a flared optical gain region that at least partially generates or amplifies an individual laser beam of the plurality of laser beams, and
   a patterned flared electrode extending in the longitudinal direction from a narrow end to a wide end, and a lateral width of the patterned flared electrode increases and decreases multiple times with position along the longitudinal direction, and wherein the narrow end is closer to the back end of the waveguide region and has lateral width smaller than that of the wide end;
a beam combiner configured to receive the plurality of laser beams from the optical array chip and generate the combined light beam;
wherein at least a portion of the waveguide region supports propagation of at least two lateral modes; and
wherein the flared optical gain region at least partially generates or amplifies an individual laser beam of the plurality of laser beams, the individual laser beam comprising a first wavelength different from wavelengths of other laser beams in the plurality of laser beams.

Example 2. The optical system of Example 1, wherein the individual optical gain element comprises a first and a second reflector and an individual light source of the plurality of light sources comprises a laser source formed by the first reflector, the second reflector, and at least a portion of the individual optical gain element therebetween.

Example 3. The optical system of Example 2, wherein the portion of the individual optical gain element comprises the flared optical gain region.

Example 4. The optical system of Example 2, wherein the individual light source comprises the flared optical gain region and the flared optical gain region amplifies a laser beam generated by the laser source.

Example 5. The optical system of Example 2, wherein the first or the second reflector is configured to sustain light having a wavelength different from a wavelength of a light beam generated by another light source of the plurality of light sources.

Example 6. The optical system of Example 1, further comprising a plurality of laser sources, wherein an individual light source comprises a laser source of the plurality of laser sources and a respective individual optical gain element of the optical array chip that receives and amplifies light generated by the laser source.

Example 7. The optical system of Example 1, wherein the waveguide region comprises a flared waveguide section comprising the flared optical gain region.

Example 8. The optical system of Example 7 wherein the waveguide region comprises a non-flared waveguide section optically couple to the flared waveguide section.

Example 9. The optical system of Example 1, further comprising an output coupler configured to receive the plurality of laser beams from the beam combiner, wherein the individual optical gain element comprises a reflector and an individual light source of the plurality of light sources comprises a laser source formed by the reflector, the individual optical gain element, the beam combiner, and the output coupler.

Example 10. The optical system of Example 9, wherein the beam combiner is configured to form a laser cavity between the reflector and the output coupler to sustain light having the first wavelength.

Example 11. The optical system of Example 1, wherein the patterned flared electrode is configured to generate an injection current distribution across the waveguide region to selectively amplify a fundamental lateral mode of the waveguide region.

Example 12. The optical system of Example 11, wherein the lateral width of the patterned flared electrode varies periodically in the longitudinal direction with a width variation period.

Example 13. The optical system of Example 11, wherein the patterned flared electrode comprises a single conductive layer.

Example 14. The optical system of Example 1, further comprising a beam transformer disposed between the optical array chip and the beam combiner, the beam transformer configured to redirect laser beams received from the optical array chip to a region of the beam combiner.

Example 15. The optical system of Example 14, wherein the beam transformer is further configured to collimate the laser beams received from the optical array chip to a region of the beam combiner.

Example 16. The optical system of any one of above Examples, wherein the beam combiner comprises a diffraction grating.

Example 17. The optical system of any one of above Examples, wherein the beam combiner comprises a plurality of dichroic beamsplitters.

Example 18. The optical system of any one of above Examples, further comprising an electronic system configured to independently control optical phases of at least a portion of the plurality of light sources.

Example 19. The optical system of Example 18, wherein the combined light beam comprises multiple light beams forming a light pattern, and wherein said electronic system is configured to adjust optical phases of at least a portion of the plurality of light sources to generate the light pattern.

Example 20. The optical system of Example 18, wherein electronic system is configured to adjust optical phases of at least a portion of the plurality of light sources to change a direction of propagation of the combined light beam.

Example 21. The optical system of Example 18, wherein electronic system dynamically adjusts the optical phases of at least a portion of the plurality of light sources to continuously scan the combined light beam within an angular range.

Example 22. The optical system of Example 1, wherein the optical array chip comprises a substrate on which the plurality of optical gain elements are monolithically fabricated.

### Example Group III

Example 1. An optical system for generating a combined light beam using a plurality of laser beams produced by a plurality of coupled external cavity lasers, the optical system comprising:
an optical array chip comprising a plurality of optical gain elements, wherein an individual optical gain element comprises a waveguide region extending from a back end to a front end of the individual optical gain element along a longitudinal direction, the waveguide region comprising a reflector, and a flared optical gain region having an output lateral width closer to the front end larger than an input lateral width closer to the back end, and
a cavity coupler region configured to couple light from an individual optical gain element to one or more other optical gain elements of the optical array chip forming the plurality of coupled external cavity lasers;
wherein at least a portion of the waveguide region supports propagation of at least two lateral modes.

Example 2. The optical system of Example 1, wherein an optical cavity of an individual external cavity laser is formed between the cavity coupler region and the reflector of the individual optical gain element.

Example 3. The optical system of Example 1, wherein the cavity coupler region is placed in a back end of the optical array chip and is configured to project light received from the back end of the individual optical gain element to a back end of another optical gain element of the optical array chip.

Example 4. The optical system of Example 1, wherein the cavity coupler region is placed in a front end of the optical array chip and is configured to project light received from the front end of the individual optical gain element to a front end of another optical gain element of the optical array chip.

Example 5. The optical system of Example 1, wherein the plurality Example 5. of coupled external cavity lasers are phase locked.

Example 6. The optical system of Example 1, wherein the reflector is disposed at the back end of the individual optical gain element.

Example 7. The optical system of Example 1, wherein the plurality of laser beams are coherently combined to generate the combined light beam.

Example 8. The optical system of Example 1, wherein the flared optical gain region comprises a patterned flared electrode configured generate an injection current distribution across the waveguide region to selectively amplify a fundamental lateral mode of the waveguide region.

Example 9. The optical system of Example 8, wherein the patterned flared electrode extends in the longitudinal direction from a narrow end to a wide end, and a lateral width of the patterned flared electrode increases and decreases multiple times with position along the longitudinal direction, and wherein the narrow end is closer to the back end of the waveguide region and has lateral width smaller than that of the wide end.

Example 10. The optical system of Example 9, wherein the lateral width of the patterned flared electrode varies periodically in the longitudinal direction with a width variation period.

Example 11. The optical system of Example 10, wherein the patterned flared electrode comprises a single conductive layer.

Example 12. The optical system of Example 1, wherein the waveguide region comprises a first waveguide section extending from the back end to an intermediate location and a second waveguide section extending from the intermediate location to the front end, the second waveguide section comprising the flared optical gain region.

Example 13. The optical system of Example 12, wherein the first waveguide section is non-flared.

Example 14. The optical system of Example 12, wherein the second waveguide section is flared.

Example 15. The optical system of Example 12, wherein the first waveguide section provides optical gain, and the reflector is disposed at the intermediate location of the individual optical gain element.

Example 16. The optical system of Example 1, wherein the flared optical gain region amplifies a laser beam received from the reflector to generate an amplified laser beam, and the combined light beam is generated by combining a plurality of amplified laser beams received from the optical array chip.

Example 17. The optical system of Example 1, further comprising an electronic system configured to adjust an optical phase of light transmitted through the individual optical gain element.

Example 18. The optical system of Example 17, further comprising a photodetector configured to receive at least a portion of an individual light beam received from an external cavity laser of the plurality of coupled external cavity lasers and generate a detector signal indicative of special distribution of optical power or radiance of the combined light beam, wherein the electronic system adjusts the optical phase of light transmitted through the individual optical gain element based at least in part on the detector signal.

Example 19. The optical system of Example 18, wherein the photodetector comprises a plurality of detector elements configured generate at least two detector signals indicative of an optical power or optical of in the combined light beam at two different spatial locations, wherein the electronic system adjusts the optical phase of light transmitted through the individual optical gain element based at least in part on the at least two detector signals.

Example 20. The optical system of Example 12, wherein a first electrode is disposed on the first waveguide section and a second electrode is disposed on the second waveguide section, the second electrode being electrically isolated from the first electrode.

Example 21. The optical system of Example 20, further comprising an electronic system configured to adjust a voltage or current provided to the first or the second electrodes to increase a radiance of the combined light beam.

Example 22. The optical system of Example 20, wherein the second electrode pumps the flared optical gain region.

Example 23. The optical system of Example 22, wherein the second electrode is a patterned flared electrode configured to generate a flared current distribution within the flared optical gain region to provide more optical gain to a fundamental lateral optical mode of the waveguide region compared to higher order lateral optical modes.

Example 24. The optical system of Example 20, wherein the first electrode or the second electrode control a phase of light transmitted the waveguide region.

Example 25. The optical system of Example 24, wherein the first electrode or the second electrode control a phase of light transmitted via a thermo-optic or an electro-optical effect.

Example 26. The optical system of Example 16, further comprising a collimator configured to collimate the plurality of laser beams.

Example 27. The optical system of Example 16, further comprising a beam combiner configured to combine the plurality of laser beams.

Example 28. The optical system of Example 16, further comprising a collimator configured to collimate the plurality of amplified laser beams.

Example 29. The optical system of Example 16, a beam propagation parameter of the combined light beam is smaller than 1.2 times a beam propagation parameter of a light beam of the plurality of amplified laser beams.

Example 30. The optical system of Example 1, wherein the beam propagation factor (M2) of the combined light beam is less than 1.5.

Example 31. The optical system of Example 16, wherein the optical array chip comprises N optical gain elements and a radiance of the combined light beam is greater than a radiance of an amplified light beam of the plurality of amplified laser beams by at least a factor within 20% of N.

### Example Group IV

Example 1. An optical system for generating a combined light beam from a plurality of laser beams produced by a plurality of evanescently coupled light sources, the optical system comprising:
a plurality of evanescently coupled waveguides, wherein an individual waveguide comprises at least a first reflector, and
an optical array chip comprising a plurality of optical gain elements, wherein an individual optical gain element of the plurality of optical gain elements comprises a waveguide region extending from a back end to a front end of the individual optical gain element along a longitudinal direction, the waveguide region comprising a second reflector and a flared optical gain region having an output lateral width closer to the front end larger than an input lateral width closer to the back end,
wherein at least a portion of the waveguide region supports propagation of at least two lateral modes; and
wherein individual waveguides of the plurality of evanescently coupled waveguides are optically connected to respective individual optical gain elements of the optical array chip to form the plurality of evanescently coupled light sources.

Example 2. The optical system of Example 1, wherein an individual evanescently coupled light sources of the plurality of evanescently coupled light sources comprises a laser source formed by the first reflector, a first portion of the waveguide region, and the second reflector.

Example 3. The optical system of Example 2, wherein an individual light source of the plurality of evanescently coupled light sources comprises the laser source and a second portion of the waveguide region that is optically coupled to the laser source and amplifies laser light generated by the laser source.

Example 4. The optical system of Example 1, wherein the plurality of evanescently coupled light sources are phase locked.

Example 5. The optical system of Example 1, wherein the second reflector is disposed at a front end of the individual optical gain element.

Example 6. The optical system of Example 5, wherein and the first reflector is disposed at a distal end of the individual waveguide with respect to the second reflector.

Example 7. The optical system of Example 1, wherein the plurality of laser beams are coherently combined to generate the combined light beam.

Example 8. The optical system of Example 1, wherein the flared optical gain region comprises a patterned flared electrode configured generate an injection current distribution across the waveguide region to selectively amplify a fundamental lateral mode of the waveguide region.

Example 9. The optical system of Example 8, wherein the patterned flared electrode extends in the longitudinal direction from a narrow end to a wide end, and a lateral width of the patterned flared electrode increases and decreases multiple times with position along the longitudinal direction, and wherein the narrow end is closer to the back end of the waveguide region and has lateral width smaller than that of the wide end.

Example 10. The optical system of Example 9, wherein the lateral width of the patterned flared electrode varies periodically in the longitudinal direction with a width variation period.

Example 11. The optical system of Example 10, wherein the patterned flared electrode comprises a single conductive layer.

Example 12. The optical system of Example 1, wherein the waveguide region comprises a first waveguide section extending from the back end to an intermediate location and a second waveguide section extending from the intermediate location to the front end, the second waveguide section comprising the flared optical gain region.

Example 13. The optical system of Example 12, wherein the first waveguide section is non-flared.

Example 14. The optical system of Example 12, wherein the second waveguide section is flared.

Example 15. The optical system of Example 12, wherein the first waveguide section provides optical gain and the second reflector is disposed at the intermediate location of the individual optical gain element.

Example 16. The optical system of Example 1, wherein the flared optical gain region amplifies a laser beam received from the second reflector to generate an amplified laser beam, and the combined light beam is generated by combining a plurality of amplified laser beams received from the optical array chip.

Example 17. The optical system of Example 1, further comprising an electronic system configured to adjust an optical phase of light transmitted through the individual optical gain element.

Example 18. The optical system of Example 17, further comprising a photodetector configured to receive at least a portion of an individual light beam received from an external cavity laser and generate a detector signal indicative of optical power or radiance of the combined light beam, wherein the electronic system adjusts the optical phase of light transmitted through the individual optical gain element based at least in part on the detector signal.

Example 19. The optical system of Example 18, wherein the photodetector comprises a plurality of detector elements configured generate at least two detector signals indicative of an optical power or optical of the combined light beam at two different spatial locations, wherein the electronic system adjusts the optical phase of light transmitted through the individual optical gain element based at least in part on the at least two detector signals.

Example 20. The optical system of Example 12, wherein a first electrode disposed on the first waveguide section and a second electrode disposed on the second waveguide section, the second electrode being electrically isolated from the first electrode.

Example 21. The optical system of Example 20, further comprising an electronic system configured to adjust a voltage or current provided to the first or the second electrode to increase a radiance of the combined light beam.

Example 22. The optical system of Example 20, wherein the second electrode pumps the flared optical gain region.

Example 23. The optical system of Example 22, wherein the second electrode is a patterned flared electrode configured to generate a flared current distribution within the flared optical gain region to provide more optical gain to a fundamental lateral optical mode of the waveguide region compared to higher order lateral optical modes.

Example 24. The optical system of Example 20, wherein the first electrode or the second electrode control a phase of light transmitted to the waveguide region.

Example 25. The optical system of Example 22, wherein the first electrode or the second electrode control a phase of light transmitted via a thermo-optic or an electro-optical effect.

Example 26. The optical system of Example 1, further comprising a collimator configured to collimate the plurality of laser beams.

Example 27. The optical system of Example 1, further comprising a beam combiner configured to coherently combine the plurality of laser beams.

Example 28. The optical system of Example 16, further comprising a collimator configured to collimate the plurality of amplified laser beams.

Example 29. The optical system of Example 16, further comprising a beam combiner configured to coherently combine the plurality of amplified laser beams.

Example 30. The optical system of Example 29, a beam propagation parameter of the combined light beam is smaller than 1.2 times a beam propagation parameter of an amplified laser beam of the plurality of amplified laser beams.

Example 31. The optical system of Example 1, wherein the beam propagation factor (M2) of the combined light beam is less than 1.5.

Example 32. The optical system of Example 16, wherein the optical system comprises N evanescently coupled light sources and a radiance of the combined light beam is greater than a radiance of an amplified laser beam of the plurality of amplified laser beams by at least a factor of N.

Example 33. The optical system of Example 1, wherein the optical array chip comprises a substrate on which the plurality of optical gain elements are monolithically fabricated.

Example 34. The optical system of Example 33, wherein the plurality of evanescently coupled waveguides are fabricated on the substrate.

Example 35. The optical system of Example 1, wherein the plurality of evanescently coupled waveguides are monolithically fabricated on a substrate.

### Terminology

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments.

Conjunctive language such as the phrase “at least one of X, Y, and Z,” unless specifically stated otherwise, is to be understood within the context used in general to convey that an item, term, etc. may be either X, Y, or Z. Thus, such conjunctive language is not generally intended to imply that certain embodiments require the presence of at least one of X, at least one of Y, and at least one of Z.

Language of degree, as used herein, such as the terms “approximately,” “about,” “generally,” and “substantially,” represent a value, amount, or characteristic close to the stated value, amount, or characteristic that still performs a desired function or achieves a desired result. For example, the terms “approximately,” “about,” “generally,” and “substantially” may refer to an amount that is within ±10% of, within ±5% of, within ±2% of, within ±1% of, or within ±0.1% of the stated amount. As another example, the terms “generally parallel” and “substantially parallel” refer to a value, amount, or characteristic that departs from exactly parallel by ±10 degrees, by ±5 degrees, by ±2 degrees, by ±1 degree, or by ±0.1 degree, and the terms “generally perpendicular” and “substantially perpendicular” refer to a value, amount, or characteristic that departs from exactly perpendicular by ±10 degrees, by ±5 degrees, by ±2 degrees, by ±1 degree, or by ±0.1 degree.

Various configurations have been described above. Although this invention has been described with reference to these specific configurations, the descriptions are intended to be illustrative of the invention and are not intended to be limiting. Various modifications and applications may occur to those skilled in the art without departing from the true spirit and scope of the invention. Thus, for example, in any method or process disclosed herein, the acts or operations making up the method/process may be performed in any suitable sequence and are not necessarily limited to any particular disclosed sequence. Features or elements from various embodiments and examples discussed above may be combined with one another to produce alternative configurations compatible with embodiments disclosed herein. Various aspects and advantages of the embodiments have been described where appropriate. It is to be understood that not necessarily all such aspects or advantages may be achieved in accordance with any particular embodiment. Thus, for example, it should be recognized that the various embodiments may be carried out in a manner that achieves or optimizes one advantage or group of advantages as taught herein without necessarily achieving other aspects or advantages as may be taught or suggested herein.

What is claimed is:

1. An optical system for generating a combined light beam by combining a plurality of light beams, the optical system comprising:
a source laser;
an optical array chip comprising a plurality of optical amplifiers configured to receive light from the source laser and output the plurality of light beams, wherein an individual optical amplifier of the plurality of optical amplifiers comprises:
a first waveguide section extending from a first end to a second end in a longitudinal direction and a second waveguide section extending from the second end to a third end in the longitudinal direction, wherein the second waveguide section comprises a flared optical gain section that has an output lateral width at the third end larger than an input lateral width at the second end, and supports propagation of at least two lateral modes,
a first electrode disposed on the first waveguide section, and
a second electrode disposed on the second waveguide section, wherein
the second electrode is electrically isolated from the first electrode;
an electronic system configured to adjust a voltage or current provided to the first electrode to increase a brightness of the combined light beam.

2. The optical system of claim 1, further comprising a photodetector configured to receive at least a portion of an individual light beam of the plurality of light beams and generate at least one detector signal indicative of optical power or radiance of the individual light beam or the combined light beam, wherein the electronic system adjusts the voltage or the current provided to the first electrode based at least in part on the at least one detector signal.

3. The optical system of claim 2, wherein the photodetector comprises a plurality of detector elements configured generate at least two detector signals indicative of optical power or optical intensity combined light beam at two different spatial locations, wherein the electronic system adjusts the voltage or the current provided to the first electrode based at least in part on the at least two detector signals.

4. The optical system of claim 1, wherein the electronic system adjusts a voltage or current provided to the first electrode to decrease a difference between an optical phase of a first light beam output by a first optical amplifier of the plurality of optical amplifiers and a second light beam output by a second different optical amplifier of the optical array chip.

5. The optical system of claim 1, wherein the second waveguide section comprises a flared optical waveguide having a lateral width that increases along the longitudinal direction.

6. The optical system of claim 1, wherein the second electrode is a patterned flared electrode configured to generate an injection current distribution across the second waveguide section to selectively amplify a fundamental lateral mode of the second waveguide section.

7. The optical system of claim 6, wherein the second electrode extends in the longitudinal direction from a narrow end to a wide end, and a lateral width of the second electrode increases and decreases multiple times with position along the longitudinal direction, and wherein the narrow end is closer to the second end of the second waveguide section and has lateral width smaller than that of the wide end.

8. The optical system of claim 7, wherein the lateral width of the second electrode varies periodically in the longitudinal direction with a width variation period.

9. The optical system of claim 8, wherein the second electrode comprises a single conductive layer.

10. The optical system of claim 1, wherein the first electrode controls a phase of light transmitted via the first waveguide section.

11. The optical system of claim 1, wherein the first electrode controls a phase of light transmitted through the first waveguide section via a thermo-optical effect or an electro-optical.

12. The optical system of claim 1, further comprising an optical distributor configured to receive light from the source laser and couple the received light to the plurality of optical amplifiers.

13. The optical system of claim 12, wherein the optical distributor comprises a network of waveguides monolithically fabricated on a substrate.

14. The optical system of claim 1, further comprising a collimator configured to collimate the light received from the plurality of optical amplifiers.

15. The optical system of claim 1, further comprising a beam combiner configured to combine the plurality of light beams from the plurality of optical amplifiers.

16. The optical system of claim 1, wherein the plurality of light beams output from the plurality of optical amplifiers are phase-locked.

17. The optical system of claim 16, wherein the combined light beam comprises a coherent combination of the plurality of light beams.

18. The optical system of claim 1, wherein optical power of one of light beam of the plurality of light beams is from 0.1 Watts to 100 Watts.

19. The optical system of claim 1, wherein a beam propagation parameter of the combined light beam is smaller than 1.2 times a beam propagation parameter a light beam of the plurality of light beams.

20. The optical system of claim 1, wherein the plurality of optical amplifiers comprises N optical amplifiers and a radiance of the combined light beam is greater than a radiance of a light beam of the plurality of light beams by at least a factor of N.
